(19) United States
(12) Patent Application Publication
(10) Pub. No.: US 2016/0365497 A1
(43) Pub. Date: Dec. 15, 2016

(54) LIGHT EMITTING DEVICE PACKAGE

(71) Applicant: SAMSUNG ELECTRONICS CO., LTD., Suwon-si (KR)

(72) Inventors: Tae Hun KIM, Bucheon-si (KR); Myong Soo CHO, Yongin-si (KR); Jung Hee KWAK, Daegu (KR); Yeon Ji KIM, Suwon-si (KR); Yong Seok KIM, Seoul (KR); Tae Kang KIM, Yongin-si (KR)

(73) Assignee: SAMSUNG ELECTRONICS CO., LTD., Suwon-si (KR)

(21) Appl. No.: 15/139,930

(22) Filed: Apr. 27, 2016

(30) Foreign Application Priority Data
Jun. 10, 2015 (KR) 10-2015-0081892

(51) Int. Cl. H01L 33/62; H01L 33/46; H01L 25/075

(52) U.S. Cl. CPC H01L 33/62; H01L 25/0753; H01L 33/46

(57) ABSTRACT

A light emitting device package includes: a package board including a first electrode structure and a second electrode structure; and a light emitting device mounted on the package board and configured to emit light, the light emitting device including: light emitting structures provided on a growth substrate, electrically connected in series, and including an input terminal and an output terminal; a first solder pad and a second solder pad electrically connected to the input terminal and the output terminal, respectively, and in contact with the first and second electrode structures; and dummy solder pads provided on the light emitting structures and electrically insulated from the light emitting structures.

### CROSS-REFERENCE TO RELATED APPLICATION

This application claims priority from Korean Patent Application No. 10-2015-0081892 filed on Jun. 10, 2015 in the Korean Intellectual Property Office, the disclosure of which is incorporated herein by reference in its entirety.

### TECHNICAL FIELD

Methods and apparatuses consistent with the example embodiments disclosed herein relate to a light emitting device package.

### BACKGROUND

A light emitting diode (LED) is a device including a material which emits light when electrical energy is applied thereto, in which energy generated through electron-hole recombination in semiconductor junction parts is converted into light to be emitted therefrom. LEDs are commonly employed as light sources in lighting devices and display devices, and thus, the development of LEDs is accelerating.

In particular, the development and employment of gallium nitride (GaN)-based LEDs has recently increased, and mobile phone keypads, turn signal lamps, and camera flashes using such gallium nitride-based LEDs have been commercialized. More generally, the development of general lighting devices using LEDs has accelerated. Light emitting devices are being implemented in a wide variety of products, such as the backlight units of large TVs, the headlamps of vehicles, and general lighting devices, and the application of such light emitting devices is gradually moving toward large-sized products having high outputs and high degrees of efficiency.

As LEDs increasingly are being applied to products having high light output requirements, a multi-cell structure including a plurality of light emitting structures is used. However, in order to apply power to each of the light emitting devices, package board designs have become increasingly complex.

### SUMMARY

An aspect of the example embodiments may provide a method for simplifying a package board design.

According to an aspect of an example embodiment, there is provided a light emitting device package including: a package board including a first electrode structure and a second electrode structure; and a light emitting device configured to emit light and mounted on the package board, wherein the light emitting device includes: light emitting structures provided on a growth substrate, electrically connected in series, and including an input terminal and an output terminal; a first solder pad and a second solder pad electrically connected to the input terminal and the output terminal, respectively, and in contact with the first and second electrode structures; and dummy solder pads provided on the light emitting structures and electrically insulated from the light emitting structures.

Each light emitting structure of the light emitting structures may include a first conductivity-type semiconductor layer, a second conductivity-type semiconductor layer, and an active layer provided between the first conductivity-type semiconductor layer and the second conductivity-type semiconductor layer, wherein in each light emitting structure of the light emitting structures, portions of the active layers and the second conductivity-type semiconductor layers are removed to expose a portion of an upper surface of the respective first conductivity-type semiconductor layers, and wherein each light emitting structure of the the light emitting structures may further include first and second electrodes respectively connected to the first and second conductivity-type semiconductor layers.

Each light emitting structure of the light emitting structures may further include a first electrode pad and a second electrode pad connected to the first and second electrodes, wherein the light emitting structures may be connected in series by a mutual connection portion connecting the first or second electrode pad of one of the light emitting structures to the first or second electrode pad of another one of the light emitting structures adjacent to the one light emitting structure.

The light emitting device package may further include a passivation layer covering the light emitting structures and having an opening exposing a region of the first or second electrode pad respectively provided at the input terminal and the output terminal of the light emitting structures.

The passivation layer may be interposed between the light emitting structures and the dummy solder pads.

The dummy solder pads may have the same shape as the first and second solder pads.

The first and second electrode structures of the package board may be in contact with the dummy solder pads.

At least one of the first and second electrode pads and at least one of the dummy solder electrodes may be connected to the first and second electrode structures.

The first and second solder pads and the dummy solder pads may have a same height, and the height may be a distance in a direction perpendicular to a surface at which the dummy solder pads contact the light emitting structures.

The dummy solder pads may be formed of a material having a composition that is the same as a composition of the first and second solder pads.

The passivation layer may include a first insulating layer having a first refractive index and a second insulating layer having a second refractive index which is stacked on the first insulating layer in an alternating fashion, to thereby form a distributed Bragg reflector (DBR).

The first insulating layer and the second insulating layer may be formed of a material selected from the group consisting of SiOₓ, SiNₓ, Al₂O₃, HfO, TiO₂, ZrO, and combinations thereof.

According to an aspect of another example embodiment, there is provided a light emitting device package including: a package board having a first electrode structure and a second electrode structure; and a light emitting device configured to emit light and mounted on the package board, wherein the light emitting device includes: light emitting structures provided on a growth substrate and comprising an input terminal and an output terminal, each of the light emitting structures including a first electrode and a second electrode; a mutual connection portion connecting one of the first or second electrodes of one of the light emitting structures to one of the first or second electrodes of another of the light emitting structures adjacent to the one light emitting structure to electrically connect the light emitting structures in series; a first solder pad and a second solder pad electrically connected to the input terminal and the output terminal, respectively, and in contact with the first and second electrode structures; and dummy solder pads provided on the light emitting structures, electrically insulated from the light emitting structures, and in contact with the first and second electrode structures.

One of the first and second solder pads and one of the dummy solder pads may be connected to the first and second electrode structures, respectively.

One of the dummy solder pads may be provided on each of the light emitting structures.

### BRIEF DESCRIPTION OF DRAWINGS

The above and other aspects, features and advantages of the example embodiments will be more clearly understood from the following detailed description taken in conjunction with the accompanying drawings, in which:

FIG. 1 is an exploded perspective view schematically illustrating a light emitting device package according to an example embodiment;

FIG. 2A is a plan view of a light emitting device of the light emitting device package of FIG. 1 viewed from direction ‘A’;

FIG. 2B is a side cross-sectional view of the light emitting device of FIG. 2A taken along line B-B′;

FIG. 3 is an equivalent circuit diagram of a light emitting device of the light emitting device package of FIG. 1;

FIGS. 4A, 4B, 5A, 5B, 6A, 6B, 7A, 7B, 8A, 8B, 9A, 9B, 10A, and 10B are views schematically illustrating a process of manufacturing a light emitting device package of FIG. 1;

FIGS. 11A and 11B are views schematically illustrating a white light source module according to an example embodiment;

FIG. 12 is a CIE 1931 color space chromaticity diagram illustrating wavelength conversion materials that may be employed in a light emitting device package according to an example embodiment;

FIG. 13 is a cross-sectional view illustrating an example in which a light emitting device package according to an example embodiment is applied to a backlight unit;

FIGS. 14 and 15 are views illustrating an example in which a light emitting device package according to an example embodiment is applied to a lighting device;

FIG. 16 is a view schematically illustrating an indoor lighting control network system in which a light emitting device package according to an example embodiment may be employed;

FIG. 17 is a view illustrating an open network system in which a light emitting device package according to an example embodiment may be employed; and

FIG. 18 is a block diagram illustrating a communications operation between a smart engine of a lighting fixture and a mobile device according to visible light communications (VLC) (or light fidelity (Li-Fi)) in which a light emitting device package according to an example embodiment may be employed.

### DETAILED DESCRIPTION

Various example embodiments will now be described more fully with reference to the accompanying drawings in which some example embodiments are shown. The example embodiments may, however, be embodied in different forms and should not be construed as limited to the example embodiments set forth herein. Rather, these example embodiments are provided so that this disclosure is thorough and complete and fully conveys the example embodiments to those skilled in the art. In the drawings, the sizes and relative sizes of layers and regions may be exaggerated for clarity.

It will be understood that when an element or layer is referred to as being “on,” “connected to” or “coupled to” another element or layer, the element or layer can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the example embodiment.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which the example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

When an example embodiment can be implemented differently, functions or operations described in a particular block may occur in a different way from a flow described in the flowchart. For example, two consecutive blocks may be performed simultaneously, or the blocks may be performed in reverse according to related functions or operations.

A light emitting diode (LED) package described hereinafter may have various components, and here, only required components will be illustrated and the contents of the example embodiments are not limited thereto.

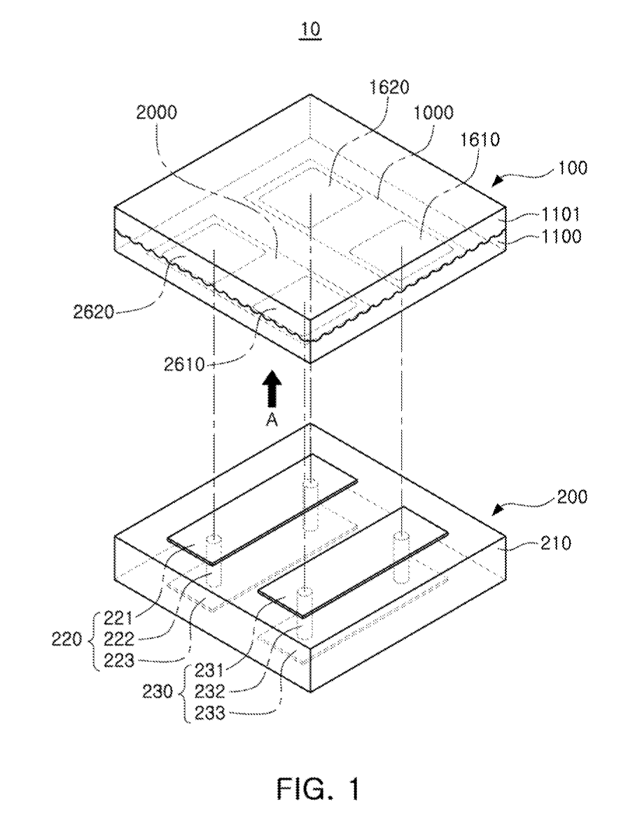

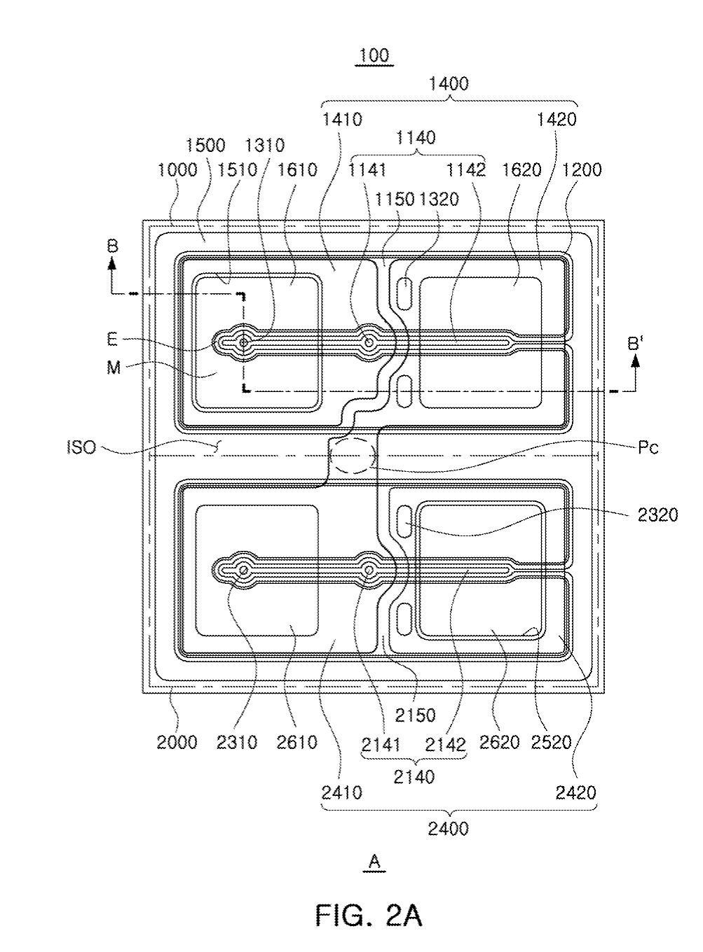

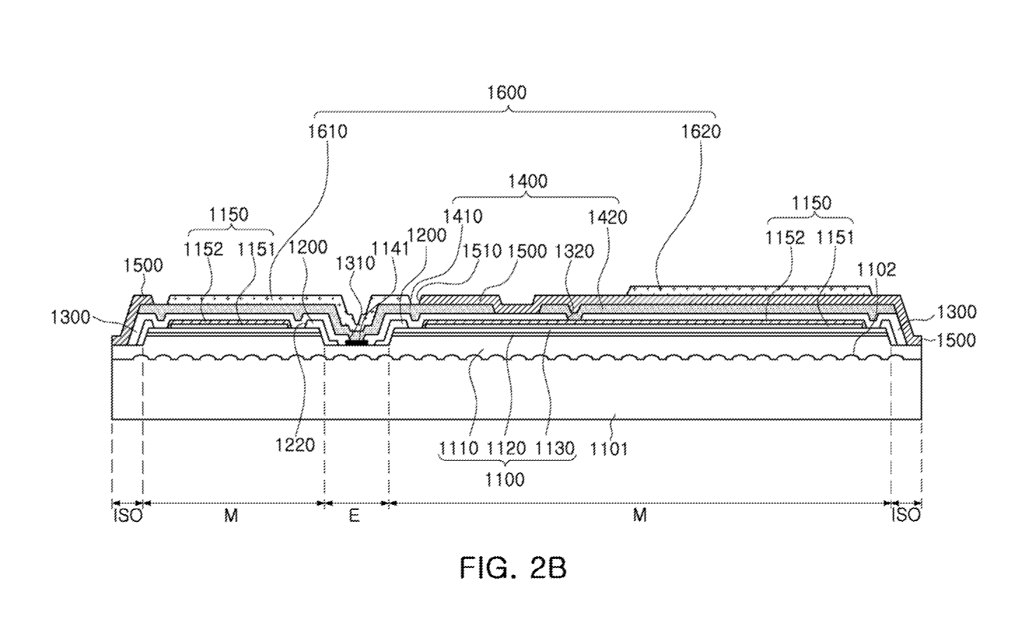

A light emitting device package according to an example embodiment will be described with reference to FIGS. 1 through 2B. FIG. 1 is an exploded perspective view schematically illustrating a light emitting device package according to an example embodiment, FIG. 2A is a plan view of a light emitting device of the light emitting device package of FIG. 1 viewed from direction ‘A’, and FIG. 2B is a side cross-sectional view of the light emitting device of FIG. 2A taken along line B-B′.

Referring to FIG. 1, a light emitting device package according to an example embodiment may include a light emitting device 100 and a package board 200.

The light emitting device 100 may have a structure in which a plurality of light emitting structures 1000 and 2000 are arranged on a growth substrate 1101. In the present example embodiment, a structure in which two light emitting structures are arranged is described as an example, but the structure is not limited thereto.

The plurality of light emitting structures 1000 and 2000 may have a structure in which a plurality of semiconductor layers are stacked. Referring to FIG. 2B, a semiconductor multilayer film 1100 includes a first conductivity-type semiconductor layer 1110, an active layer 1120, and a second conductivity-type semiconductor layer 1130 sequentially stacked on the growth substrate 1101. The plurality of light emitting structures 1000 and 2000 may be formed through an isolation process of exposing a surface of the growth substrate 1101 by completely removing the semiconductor multilayer film 1100. Also, the plurality of light emitting structures 1000 and 2000 may be formed through a partial separation (mesa etching) process of exposing the first conductivity-type semiconductor layer 1110. In the present example embodiment, a case in which an isolation region (ISO) is formed through a partial separation process will be described as an example. Since the semiconductor multilayer film 1100 grown in the single growth substrate 1101 is separated to form the plurality of light emitting structures 1000 and 2000, the plurality of light emitting structures 1000 and 2000 may be disposed to share the single growth substrate 1101. Hereinafter, a case in which a plurality of light emitting structures are two light emitting structures, that is, the first light emitting structure 1000 and the second light emitting structure 2000, will be described as an example. Also, hereinafter, a configuration of the first light emitting structure 1000 will be mainly described, and descriptions of the same components of the second light emitting structure 2000 as that of the first light emitting structure 1000 will be omitted.

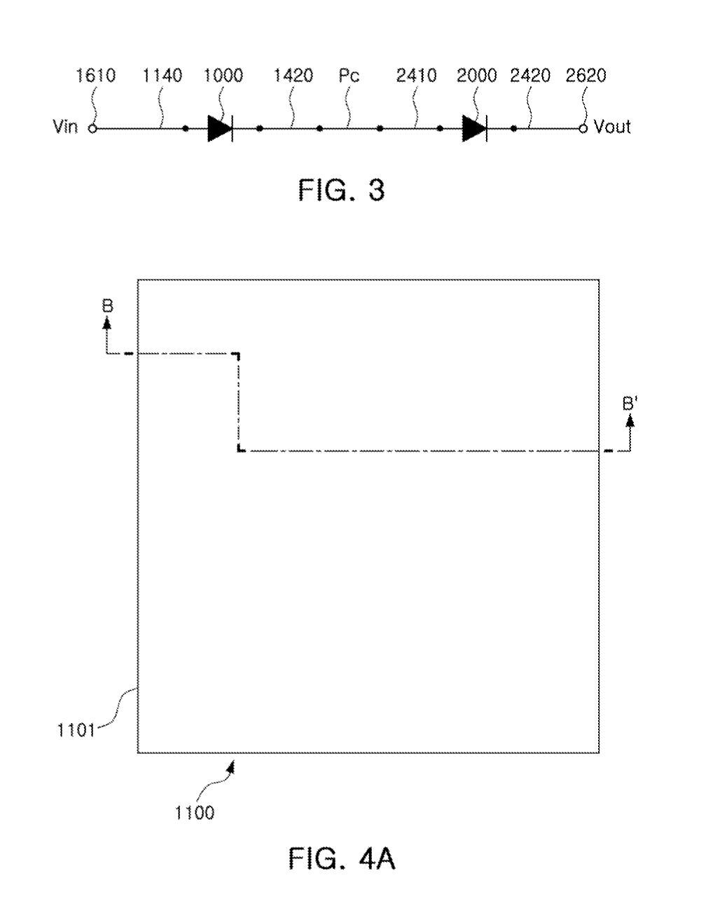

The first and second light emitting structures 1000 and 2000 of the light emitting device 100 may have a structure in which the first and second light emitting structures 1000 and 2000 are electrically connected in series as illustrated in the equivalent circuit diagram of FIG. 3. The number of the light emitting structures connected in series may be variously selected from the number of light emitting structures within a range appropriate for a voltage standard. For example, in a case in which a desired voltage standard is 12V, and 3V is applied to each of the light emitting structures, four light emitting structures may be connected in series.

As illustrated in FIG. 2A, first electrodes 1140 and 2140 and second electrodes 1150 and 2150 to which power is applied may be disposed in the first and second light emitting structures 1000 and 2000. Also, in the first electrodes 1140 and 2140 and the second electrodes 1150 and 2150, first electrode pads 1410 and 2410 and second electrode pads 1420 and 2420 are disposed to prepare first and second solder pads 1610 and 2620 for connection with the first and second electrode structures 220 and 230 of the package board 200, respectively.

In order to electrically connect the first and second light emitting structures 1000 and 2000 in series, at least one mutual connection portion Pc may be disposed to electrically connect the first and second light emitting structures 1000 and 2000. That is, as illustrated in FIG. 3, the mutual connection portion Pc may connect the electrodes having the opposite polarities of the adjacent light emitting structures 1000 and 2000 to realize a serial connection. In detail, as illustrated in FIG. 2A, the second electrode pad 1420 of the first light emitting structure 1000 and the first electrode pad 2410 of the second light emitting structure 2000 may be connected by the mutual connection portion Pc to electrically connect the first and second light emitting structures 1000 and 2000 in series. This configuration will be described in detail hereinafter.

As illustrated in FIGS. 2A and 2B, the first light emitting structure 1000 may be disposed on a growth substrate 1101 and may include a semiconductor multilayer film 1100 including the first conductivity-type semiconductor layer 1110, the active layer 1120, and the second conductivity-type semiconductor layer 1130. The first and second electrodes 1140 and 1150 may be disposed on the first and second conductivity-type semiconductor layer 1110 and 1130, respectively. The first light emitting structure 1000 may include first and second insulating layers 1200 and 1300, an electrode pad 1400, a passivation layer 1500, and a solder pad 1600.

The growth substrate 1101 may have an upper surface extending in x and y directions. The growth substrate 1101 may be provided as a semiconductor growth substrate and may be formed of an insulating, a conductive, or a semiconductive material such as sapphire, silicon (Si), SiC, MgA₁₂O₄, MgO, LiAlO₂, LiGaO₂, or GaN. Sapphire, commonly used as a material of a nitride semiconductor growth substrate, is a crystal having electrical insulating properties, having Hexa-Rhombo R3c symmetry, and having a lattice constant of 13,001 Å on a c-axis and a lattice constant of 4,758 Å on an a-axis. Sapphire has a C (0001) plane, an A (11-20) plane, and an R (1-102) plane. According to an example embodiment, the C plane, among the various types of planes, is primarily used as a nitride growth substrate because the C plane facilitates the growth of a nitride thin film and is stable at high temperatures.

As illustrated in FIG. 2B, an irregular pattern 1102 may be formed on an upper surface of the growth substrate 1101, namely, on a growth surface of the semiconductor multilayer film 1100, and crystallinity, light emitting efficiency, and the like, of the semiconductor layers, may be enhanced by the irregular pattern 1102. In the present example embodiment, the irregular pattern 1102 is illustrated as having a dome-like convex shape, but a shape of the irregular pattern 1102 is not limited thereto. For example, the irregular pattern 1102 may have various shapes such as a quadrangular shape, a triangular shape, other shapes having any combination of flat or curved shapes, and the like. Also, the irregular pattern 1102 may be selectively formed and provided, and may be omitted according to example embodiments.

In some example embodiments, the growth substrate 1101 may be micro-polished through chemical mechanical polishing (CMP) in a direction from the surface of the growth substrate 1101 on which the semiconductor multilayer film 1100 is disposed towards the other surface of the growth substrate 1101 opposing the surface thereof on which the semiconductor multilayer film 1100 is disposed to reduce a thickness of the growth substrate 1101. Here, CMP refers to a method of planarizing a surface of a target to be treated through a composite chemical and mechanical action. However, the method is not limited thereto and a method of partially chemically etching the other surface of the growth substrate 1101 may also be applied, and in a case in which the growth substrate 1101 is sufficiently thin, the thickness reduction process may be omitted.

A buffer layer may be formed on an upper surface of the growth substrate 1101. The buffer layer, serving to alleviate lattice defects in the semiconductor layers grown on the growth substrate 1101, may be formed as an undoped semiconductor layer formed of a nitride, or the like. For example, the buffer layer may alleviate a difference in lattice constants between the growth substrate 1101 formed of sapphire and the first conductivity-type semiconductor layer 1110 formed of GaN and stacked thereon to increase crystallinity of the GaN layer. In this case, undoped GaN, AlN, InGaN, and the like, may be applied as the buffer layer, and the buffer layer may be grown to have a thickness ranging from tens to hundreds of Å at low temperatures ranging from 500° C. to 600° C. According to an example embodiment, undoped refers to a semiconductor layer on which an impurity doping process has not been performed. The semiconductor layer may have an inherent level of impurity concentration. For example, when a gallium nitride semiconductor is grown using a metal organic chemical vapor deposition (MOCVD) process, silicon (Si) or the like, which is used as a dopant, may be included therein in an amount ranging from about 10¹⁴ to 10¹⁸/cm³, although the inclusion of this element may not be intentional. Also, the buffer layer may be omitted according to certain example embodiments.

The first conductivity-type semiconductor layer 1110 stacked on the growth substrate 1101 may be formed of a semiconductor doped with an n-type impurity and may be an n-type nitride semiconductor layer. Also, the second conductivity-type semiconductor layer 1130 may be formed of a semiconductor doped with a p-type impurity and may be a p-type nitride semiconductor layer. However, according to example embodiments, the first and second conductivity-type semiconductor layers 1110 and 1130 may be interchanged in terms of position so as to be stacked. The first and second conductivity-type semiconductor layers 1110 and 1130 may have an empirical formula AlₓIn_{y}Ga_{(1-x-y)}N, where 0≦x≦1, 0≦y≦1, and 0≦x+y≦1, and, for example, materials such as GaN, AlGaN, InGaN, or AlInGaN may correspond thereto.

The active layer 1120 disposed between the first and second conductivity-type semiconductor layers 1110 and 1130 may emit light having a predetermined level of energy through electron-hole recombination. The active layer 1120 may include a material having an energy band gap smaller than those of the first and second conductivity-type semiconductor layers 1110 and 1130. For example, in a case in which the first and second conductivity-type semiconductor layers 1110 and 1130 are formed of a GaN-based compound semiconductor, the active layer 1120 may include an InGaN-based compound semiconductor having an energy band gap smaller than that of GaN. Also, the active layer 1120 may have a multi-quantum well (MQW) structure in which quantum well layers and quantum barrier layers are alternately stacked, for example, an InGaN/GaN structure. However, without being limited thereto, the active layer 1120 may also have a single quantum well (SQW) structure.

As illustrated in FIG. 2A, the light emitting structure 1000 may include an etched region E in which portions of the second conductivity-type semiconductor layer 1130, the active layer 1120, and the first conductivity-type semiconductor layer 1110 are etched, and a plurality of mesa regions M partially demarcated by the etched region E. Also, the isolation region ISO may be disposed around the plurality of light emitting structures 1000 and 2000.

The etched region E may have a gap structure separated from one side of the first light emitting structure 1000 having a quadrangular shape to the other side of the first light emitting structure 1000 opposed thereto to have a predetermined thickness and length, and a plurality of etched regions E may be arranged to be parallel to each other on an inner side of the quadrangular region of the first light emitting structure 1000. Thus, the plurality of etched regions E may be surrounded by the mesa regions M.

A first electrode 1140 may be disposed on an upper surface of the first conductivity-type semiconductor layer 1110 exposed to the etched region E, and connected to the first conductivity-type semiconductor layer 1110, and a second electrode 1150 may be disposed on an upper surface of each of the plurality of mesa regions M and connected to the second conductivity-type semiconductor layer 1130. The first and second electrodes 1140 and 1150 may be disposed on a surface of the light emitting device 100 on which the first light emitting structure 1000 is positioned. Thus, the first and second electrodes 1140 and 1150 may be disposed on the same surface of the light emitting device 100 to allow the light emitting device 100 to be mounted on a package board 200 in a flip-chip manner, as described hereinafter.

As illustrated in FIG. 2A, the first electrode 1140 of the first light emitting structure 1000 may include a plurality of pad portions 1141 and a plurality of finger portions 1142 having a width smaller than that of the pad portions 1141 and extending from the plurality of pad portions 1141, respectively, along the etched regions E. A plurality of first electrodes 1140 may be arranged to be spaced apart from one another so as to be evenly distributed on the entirety of the first conductivity-type semiconductor layer 1110. In this manner, when the plurality of first electrodes 1140 are disposed, a current applied to the first conductivity-type semiconductor layer 1110 may be evenly applied to the entirety of the first conductivity-type semiconductor layer 1110 through the plurality of first electrodes 1140.

The plurality of pad portions 1141 may be disposed to be spaced apart from one another, and the plurality of finger portions 1142 may connect the plurality of pad portions 1141. The plurality of finger portions 1142 may have different widths. For example, when the first electrode 1140 has two finger portions 1142 as in the present example embodiment, a width of any one finger portion 1142 may be greater than that of the other finger portion 1142. The width of the finger portions 1142 may be adjusted in consideration of resistance of a current injected through the first electrode 1140.

As illustrated in FIG. 2B, the second electrode 1150 may include a reflective metal layer 1151. Also, the second electrode 1150 may further include a metal coating layer 1152 covering the reflective metal layer 1151. The metal coating layer 1152 may be selectively provided and may be omitted according to example embodiments. The second electrode 1150 may cover an upper surface of the second conductivity-type semiconductor layer 1130 defining an upper surface of the mesa region M.

In order to cover the active layer 1120 exposed to the etched region E, a first insulating layer 1200 formed of an insulating material may be provided on the light emitting structure 1000 including a side surface of the mesa region M. For example, the first insulating layer 1200 may be formed of an insulating material including SiO₂, SiOₓN_{y}, TiO₂, Al₂O₃, or ZrO₂. Also, the first insulating layer 1200 may be provided such that the first and second electrodes 1140 and 1150 are exposed. The first insulating layer 1200 may be selectively provided and may be omitted according to example embodiments.

The second insulating layer 1300 may be provided on the first light emitting structure 1000 and cover the entirety of the light emitting structure 1000. The second insulating layer 1300 may be primarily formed of a material having insulating characteristics, and may be formed of an inorganic or organic material. For example, the second insulating layer 1300 may be formed of an epoxy-based insulating resin. Also, the second insulating layer 1300 may include a silicon oxide or a silicon nitride and may be formed of, for example, SiO₂, SiOₓN_{y}, TiO₂, Al₂O₃, or ZrO₂.

The second insulating layer 1300 may include a plurality of openings 1310 and 1320 disposed on the first electrode 1140 and the second electrode 1150, respectively. In detail, the plurality of openings 1310 and 1320 may include a first opening 1310 and a second opening 1320 provided in positions corresponding to the first electrode 1140 and the second electrode 1150, respectively. The first opening 1310 and the second opening 1320 may partially expose the first electrode 1140 and the second electrode 1150.

In particular, the first opening 1310 disposed on the first electrode 1140 may only expose the pad portion 1141 of the first electrode 1140. Thus, the first opening 1310 may be disposed in a position corresponding to the pad portion 1141 on the first electrode 1140.

An electrode pad 1400 may be insulated from the first and second conductivity-type semiconductor layers 1110 and 1130 by the second insulating layer 1300 covering the entirety of an upper surface of the light emitting structure 1000. The electrode pad 1400 may be connected to the first electrode 1140 and the second electrode 1150 partially exposed through the plurality of openings 1310 and 1320 so as to be electrically connected to the first and second conductivity-type semiconductor layers 1110 and 1130.

Electrical connections between the electrode pad 1400 and the first and second conductivity-type semiconductor layers 1110 and 1130 may be variously adjusted by the plurality of openings 1310 and 1320 provided in the second insulating layer 1300. For example, electrical connections between the electrode pad 1400 and the first and second conductivity-type semiconductor layers 1110 and 1130 may be variously modified according to the number and positions of the plurality of openings 1310 and 1320.

The electrode pad 1400 may be provided in a quantity of at least two including a first electrode pad 1410 and a second electrode pad 1420. Namely, the first electrode pad 1410 may be electrically connected to the first conductivity-type semiconductor layer 1110 via the first electrode 1140 and the second electrode pad 1420 may be electrically connected to the second conductivity-type semiconductor layer 1130 via the second electrode 1150. According to this configuration, the first opening 1310 exposing the first electrode 1140 may be disposed in a position in which the first opening 1310 overlaps the first electrode pad 1410, and the opening 1320 exposing the second electrode 1150 may be disposed in a position in which the opening 1320 overlaps the second electrode pad 1420. The first and second electrode pads 1410 and 1420 may be separated and electrically insulated from each other. The electrode pad 1400 may be formed of a material including one or more of gold (Au), aluminum (Al), tungsten (W), platinum (Pt), silicon (Si), iridium (Ir), silver (Ag), copper (Cu), nickel (Ni), titanium (Ti), chromium (Cr), and alloys thereof, for example, and may have a multilayer structure.

Among the first electrodes 1140, the first electrode 1140 disposed in a position in which the second electrode pad 1420 is positioned thereabove such that the first electrode 1140 overlaps the second electrode pad 1420 may need to be prevented from being electrically connected to the second electrode pad 1420. To this end, the second insulating layer 1300 may not have the opening 1310 exposing the pad portion 1141 of the first electrode 1140, in the portion in which the second electrode pad 1420 is positioned thereabove.

In detail, as illustrated in FIG. 2A, in the case in which the first contact electrode 1140 includes two pad portions 1141 and two finger portions 1142, the openings 1310 exposing the pad portions 1141 may only be provided on the two pad portions 1141 disposed in positions in which the two pad portions 1141 overlap the first electrode pad 1410. Thus, the pad portion 1141 of the first electrode 1140 positioned below the first electrode pad 1410 may be connected to the first electrode pad 1410 via the opening 1310, but since the opening 1310 is not provided below the second electrode pad 1420, the pad portion 1141 and the second electrode pad 1420 may be electrically insulated from one another. As a result, through the arrangement structure of the plurality of openings 1310 and 1320 respectively exposing the first contact electrode 1140 and the second contact electrode 1150, the first electrode pad 1410 may be connected to the first contact electrode 1140 and the second electrode pad 1420 may be connected to the second contact electrode 1150.

Meanwhile, similar to the configuration in which the first and second electrode pads 1410 and 1420 are disposed in the first light emitting structure 1000, first and second electrode pads 2410 and 2420 may be disposed in the second light emitting structure 2000. Also, a mutual connection portion Pc electrically connecting the second electrode pad 1420 and the first electrode pad 2410 may be further disposed between the second electrode pad 1420 of the first light emitting structure 1000 and the first electrode pad 2410 of the second light emitting structure 2000. The mutual connection portion Pc may electrically connect the second electrode pad 1420 and the first electrode pad 2410 to electrically connect the first light emitting structure 1000 and the second light emitting structure 2000 in series. The mutual connection portion Pc, the second electrode pad 1420, and the first electrode pad 2410 may be formed through a single process. In a case in which three or more light emitting structures are disposed, two or more mutual connection portions Pc may be disposed in order to electrically connect the light emitting structures in series.

A passivation layer 1500 is provided on the electrode pad 1400 and covers the entirety of the electrode pad 1400. The passivation layer 1500 may be disposed to cover the entirety of the first and second light emitting structures 1000 and 2000. According to example embodiments, a single passivation layer 1500 covering the first and second light emitting structures 1000 and 2000 may be disposed, or separate passivation layers may be disposed on the light emitting structures 1000 and 2000, individually. Bonding regions 1510 and 2520 may be formed in the passivation layer 1500 to partially expose the electrode pad 1400. At least one bonding region 1510 or 2520 may be disposed on each of the electrode pads in order to partially expose the first electrode pad 1410 of the first light emitting structure 1000 and the second electrode pad 2420 of the second light emitting structure 2000. The bonding regions 1510 and 2520 may function as an input terminal and an output terminal of the first and second light emitting structures 1000 and 2000 connected in series such that power may be applied only through the bonding regions 1510 and 2520.

In the present example embodiment, the figures exemplarily illustrate that two bonding regions 1510 and 2520 are disposed to be symmetrical to each other in a diagonal direction of the light emitting device 100, but the bonding regions are limited thereto, and the number and arrangement of the bonding regions 1510 and 2520 may be variously modified.

The passivation layer 1500 may be formed of a silicon oxide or a silicon nitride having insulating properties and light-transmissive characteristics, and for example, the passivation layer 1500 may be formed of SiO₂, SiN, SiOₓN_{y}, TiO₂, Si₃N₄, Al₂O₃, TiN, AlN, ZrO₂, TiAlN, or TiSiN. Also, the passivation layer 1500 may be formed of the same material as that of the second insulating layer 1300.

The passivation layer 1500 may form a distributed Bragg reflector (DBR) by alternately stacking a first insulating layer having a first refractive index and a second insulating layer having a second refractive index. When the passivation layer 1500 is formed as a DBR, the passivation layer 1500 may reflect light, among light emitted by the active layer 1120, traveling in the opposite direction of the growth substrate 1101, to redirect the light in a direction of the growth substrate 1101, and thus, light extraction efficiency of the light emitting device package 10 may be enhanced.

For example, when a wavelength of light generated by the active layer 1120 is λ and a refractive index of a corresponding layer is n, the first insulating layer and the second insulating layer may have a thickness of λ/4n, substantially having a thickness ranging from about 300 Å to 900 Å. According to an example embodiment, in the passivation layer 1500, reflective indices and thicknesses of the first insulating layer and the second insulating layer may be selectively designed to obtain a high degree of reflectivity (95% or greater) with respect to a wavelength of light generated by the active layer 1120.

As illustrated in FIG. 2A, first and second solder pads 1610 and 2620 may be disposed in the bonding regions 1510 and 2520, respectively, and dummy solder pads 1620 and 2610 may be disposed in a plurality of regions of the passivation layer 1500. According to example embodiments, the term “dummy” is used to refer to a component which is provided as only a part of a pattern, rather than a component which performs a substantial function, within the light emitting device 100, although the dummy has a structure and shape the same as or similar to other components. Thus, an electrical signal is not intended to be applied to the “dummy” component, and even when an electrical signal is applied to the “dummy” component, the “dummy” component does not electrically perform the same function as the other components. In the present example embodiment, “dummy solder pad” refers to a solder pad configured such that power is not applied to the light emitting structures 1000 and 2000 even in the case that power is applied to the dummy solder pad.

The first and second solder pads 1610 and 2620 may be connected to the first and second electrode pads 1410 and 2420 partially exposed through the bonding regions 1510 and 2520. The first and second solder pads 1610 and 2620 may be electrically connected to the first conductivity-type semiconductor layers 1110 and 2110 and the second conductivity-type semiconductor layers 1130 and 2130 of the plurality of light emitting structures 1000 and 2000 via the electrode pad 1400, respectively. Thus, the first and second solder pads 1610 and 2620 may be disposed in an input terminal and an output terminal of the plurality of light emitting structures 1000 and 2000, respectively, and used for the purpose of applying power to the first and second light emitting structures 1000 and 2000 connected in series. The input terminal may receive a Vin and the output terminal may output Vout. The solder pads 1600 may be formed of a material including one or more of nickel (Ni), gold (Au), copper (Cu), and alloys thereof. The dummy solder pads 1620 and 2610 may be disposed on the passivation layer 1500 and electrically insulated from the first and second light emitting structures 1000 and 2000. Also, the first and second solder pads 1610 and 2620 and the plurality of dummy solder pads 1620 and 2610 may be disposed in positions in contact with the first and second electrode structures 220 and 230. Through this configuration, the first and second solder pads 1610 and 2620 and the plurality of dummy solder pads 1620 and 2610 may be used to mount the light emitting device 100 on the first and second electrode structures 220 and 230.

The first and second solder pads 1610 and 2620 and the dummy solder pads 1620 and 2610 may be disposed on substantially the same level (e.g., the same height). In FIG. 2B, it is exemplarily illustrated that the dummy solder pad 1620 is disposed higher than the first solder pad 1610, but in actuality, according to an example embodiment, the passivation layer 1500 is thinner than the first solder pad 1610 and the dummy solder pad 1620, and thus, the first solder pad 1610 and the dummy solder pad 1620 may be disposed on substantially the same level.

Thus, when the light emitting device 100 is mounted on the package board 200, a problem in which the light emitting device 100 is tilted or damaged may be fundamentally prevented.

The first and second solder pads 1610 and 2620 and the dummy solder pads 1620 and 2610 may be, for example, under bump metallurgy (UBM) layers. The first and second solder pads 1610 and 2620 and the dummy solder pads 1620 and 2610 may respectively be provided as a single layer or multiple layers. In the present example embodiment, it is exemplarily illustrated that a single first solder pad 1610 and a single second solder pad 2620 are provided, but the number of the first solder pad 1610 and the second solder pad 2620 is not limited thereto and the number and structure of the first solder pad 1610 and the second solder pad 2620 may be adjusted according to the bonding regions 1510 and 2520.

Solder bumps may be disposed on the first and second solder pads 1610 and 2620 and the dummy solder pads 1620 and 2610. The solder bumps are conductive adhesives for mounting the light emitting device 100 on the package board 200 in a flip-chip manner. Sn solder may be used as the solder bumps, and a small amount of a material such as silver (Ag) or copper (Cu) may be contained in the Sn solder.

As illustrated in FIG. 1, the package board 200 on which the light emitting device 100 is mounted may have first and second electrode structures 220 and 230. In the first and second electrode structures 220 and 230, first and second via electrodes 222 and 232 penetrating through one surface of the package board 200 on which the light emitting device 100 is mounted and the other surface opposing the one surface may be disposed in the thickness direction (e.g., the vertical direction in FIG. 1). The first bonding pads 221 and 223 and the second bonding pads 231 and 233 are provided on one surface and the other surface of the package board 200 to which both ends of the first and second via electrodes 222 and 232 are exposed, to electrically connect both surfaces of the package board 200.

The package board 200 may be formed using a package body 210 formed of a material such as silicon (Si), sapphire, ZnO, GaAs, SiC, MgAl₂O₄, MgO, LiAlO₂, LiGaO₂, or GaN. In the present example embodiment, a silicon substrate may be used. However, a material of the package body 210 is not limited thereto, and the package body 210 may be formed of a material such as an organic resin material including epoxy, triazine, silicone, or polyimide, and other organic resin materials in consideration of heat dissipation characteristics and electrical connection relationships of the light emitting device package. In order to enhance heat dissipation characteristics and luminous efficiency, the package body 210 may be formed of a ceramic material having characteristics such as high heat resistance, excellent heat conductivity, and high reflectivity, for example, Al₂O₃, or AlN.

Also, in addition to the aforementioned substrate, a printed circuit board (PCB) or a lead frame may also be used as the package board 200.

In the present example embodiment, since the electrically connected solder pads are disposed on the electrodes disposed on the output terminal and the input terminal, among the electrodes of the plurality of light emitting structures connected in series, and the electrically insulated dummy solder pads are disposed on the other electrodes, there is no need to change a design of the package board even in the case that the disposition of the plurality of light emitting structures is changed, obtaining an effect of reducing manufacturing time and manufacturing costs. In addition, since the dummy solder pads are even disposed on the electrodes other than those disposed at the output terminal and the input terminal, the problem in which the light emitting device is tilted or damaged due to unbalanced solder may be fundamentally resolved.

Hereinafter, a process of manufacturing the light emitting device of FIG. 1 will be described.

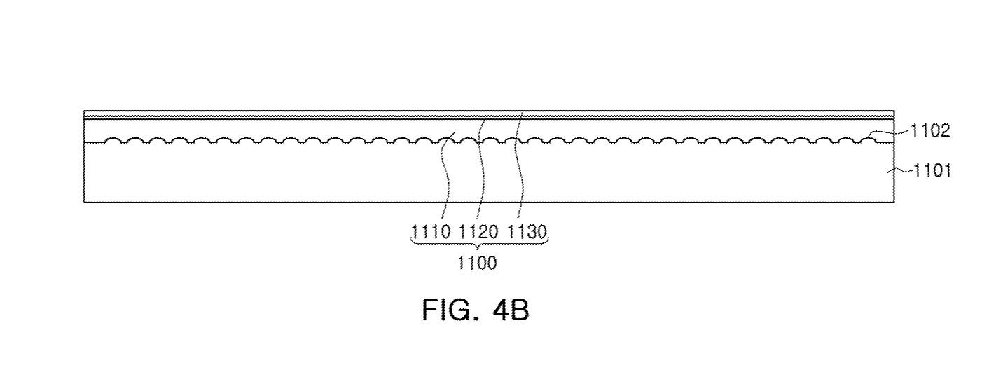

FIGS. 4A through 10B are views schematically illustrating a process of manufacturing a light emitting device package of FIG. 1. In FIGS. 4A through 10B, reference numerals which are the same as those of FIGS. 1 through 2B denote the same members, and thus, redundant descriptions thereof will be omitted. Also, a case in which a plurality of light emitting structures are two light emitting structures, that is, the first light emitting structure 1000 and the second light emitting structure 2000, will be described as an example. However, it is understood that example embodiments are not limited thereto, and more than two light emitting structures may be employed. Also, hereinafter, the configuration of the first light emitting structure 1000 will primarily be described, and descriptions of the same components of the second light emitting structure 2000 as those of the first light emitting structure 1000 will be omitted.

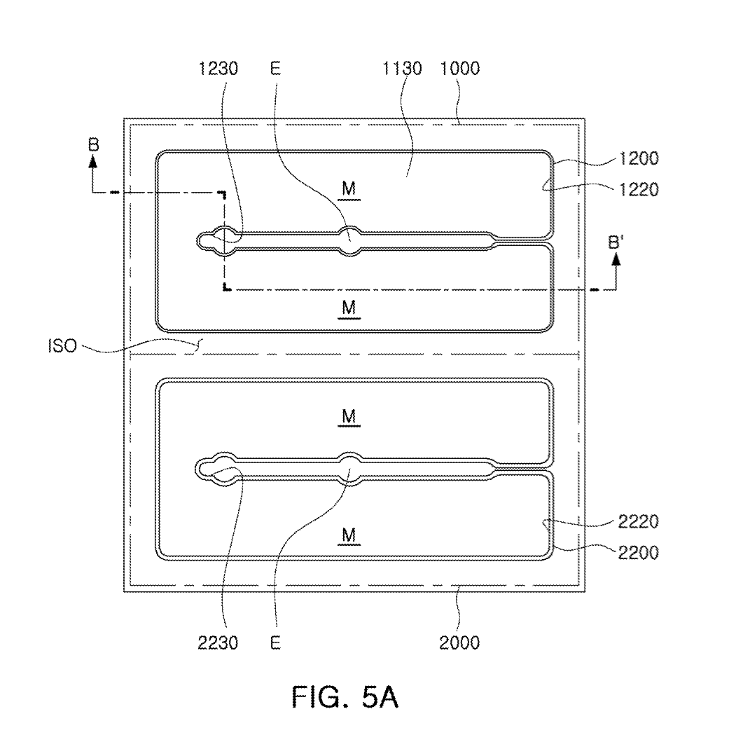

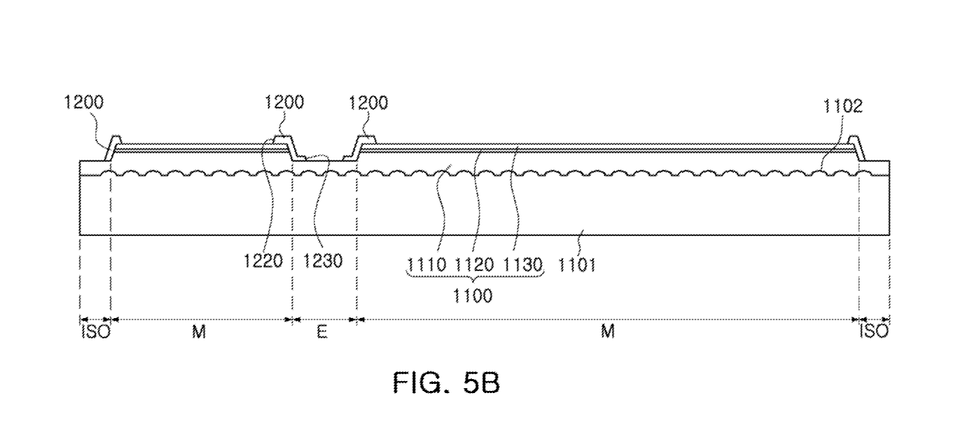

Referring to FIGS. 4A and 4B, FIG. 4A is a plan view of a semiconductor multiple film 1100 formed on a growth substrate 1101, and FIG. 4B is a cross-sectional view taken along line A-A′ of FIG. 4A. FIGS. 5A through 10B are illustrated in the same manner.

First, the irregular pattern 1102 may be formed on the growth substrate 1101. However, the irregular pattern 1102 may also be omitted according to other example embodiments. A substrate formed of a material such as sapphire, Si, SiC, MgAl₂O₄, MgO, LiAlO₂, LiGaO₂, or GaN as described above may be used as the growth substrate 1101.

Next, a first conductivity-type semiconductor layer 1110, an active layer 1120, and a second conductivity-type semiconductor layer 1130 may be sequentially grown on the growth substrate 1101 using metal-organic chemical vapor deposition (MOCVD), hydride vapor phase epitaxy (HVPE), or molecular beam epitaxy (MBE) to form a semiconductor multilayer film 1100 having a stacked structure of a plurality of semiconductor layers. The first conductivity-type semiconductor layer 1110 and the second conductivity-type semiconductor layer 1130 may be an n-type semiconductor layer and a p-type semiconductor layer, respectively. In the semiconductor multilayer film 1100, the positions of the first conductivity-type semiconductor layer 1110 and the second conductivity-type semiconductor layer 1130 may be interchanged, and the second conductivity-type semiconductor layer 1130 may first be formed on the growth substrate 1101.

Referring to FIGS. 5A and 5B, portions of the second conductivity-type semiconductor layer 1130, the active layer 1120, and the first conductivity-type semiconductor layer 1110 may be etched to expose at least a portion of the first conductivity-type semiconductor layer 1110. Accordingly, etched regions E and a plurality of mesa regions M partially demarcated by the etched regions E may be formed. Also, an isolation region ISO may be formed to separate the semiconductor multilayer film 1100 into the first and second light emitting structures 1000 and 2000.

During the etching process, a mask layer may be formed in a region excluding a region in which the first conductivity-type semiconductor layer 1110 is exposed, and wet etching or dry etching may be subsequently performed to form the mesa regions M. According to example embodiments, the etching process may be performed such that the first conductivity-type semiconductor layer 1110 is not etched and only a portion of an upper surface thereof is exposed.

A first insulating layer 1200 may be formed on a side surface of the mesa region M exposed to the etched region E through the etching process. The first insulating layer 1200 may be formed to cover the side surface of the mesa region M including an edge of an upper surface of the mesa region M and a portion of a bottom surface of the etched region E. Thus, the active layer 1120 exposed by the etched region E may be covered by the first insulating layer 1200 so as not to be exposed outwardly. Openings 1220 and 1230, in which electrodes of a light emitting structure are to be disposed in a follow-up process, may be formed in regions of the first insulating layer 1200 on the mesa region M. However, the first insulating layer 1200 may be selectively formed and may be omitted according to example embodiments. The first insulating layer 2200 may also be formed in the second light emitting structure 2000 in the same manner as the first insulating layer 1200 and may be integrally formed with the first insulating layer 1200 of the first light emitting structure 1000. Also, openings 2200 and 2230 may also be formed in the second light emitting structure 2000.

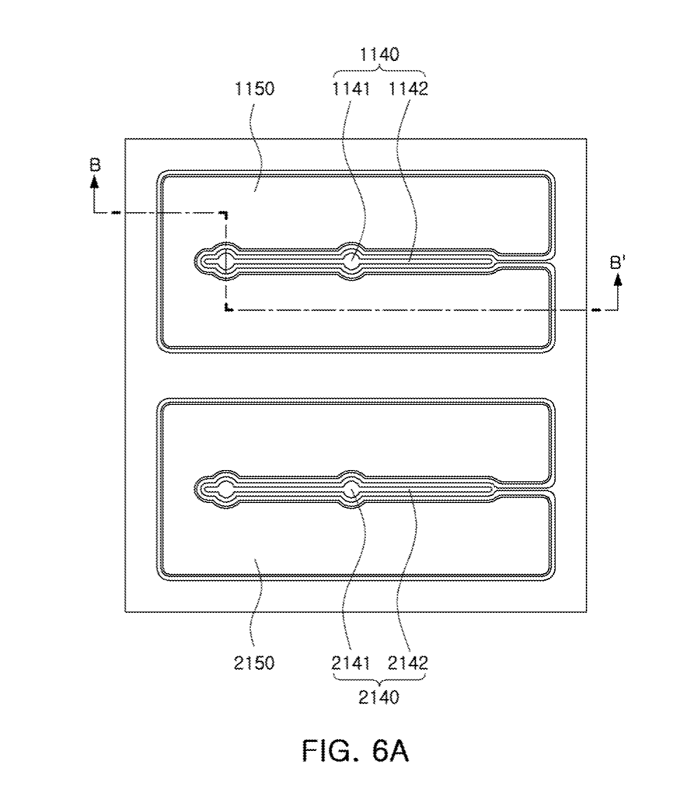

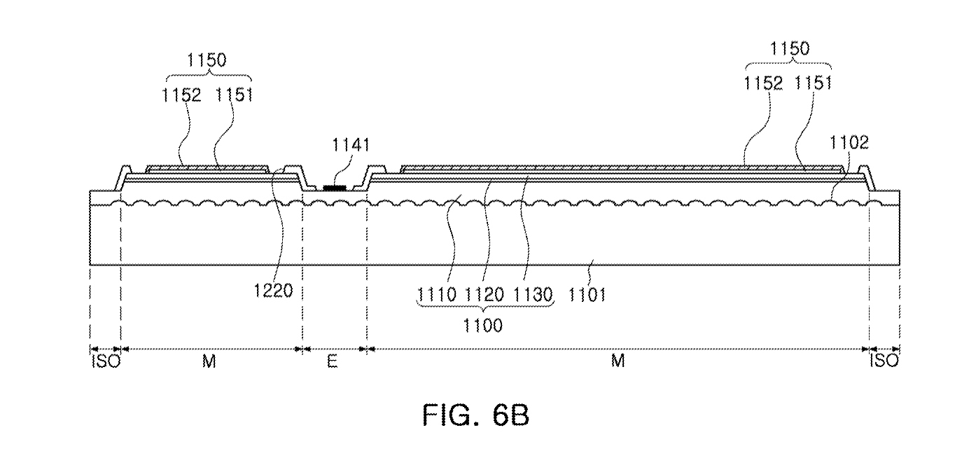

Referring to FIGS. 6A and 6B, a first electrode 1140 and a second electrode 1150 may be formed in the etched region E and the mesa region M, respectively. The first electrode 1140 may extend along the etched region E and may be connected to the first conductivity-type semiconductor layer 1110 defining a bottom surface of the etched region E. The second electrode 1150 may be connected to the second conductivity-type semiconductor layer 1130.

The first electrode 1140 may include a plurality of pad portions 1141 and a plurality of finger portions 1142 extending from the pad portions 1141. The second electrode 1150 may include a reflective metal layer 1151. The second electrode 1150 may further include a metal coating layer 1152 covering the reflective metal layer 1151. First and second electrodes 2140 and 2150, the plurality of pad portions 2141, and a plurality of finger portions 2142 may also be formed in the second light emitting structure 2000.

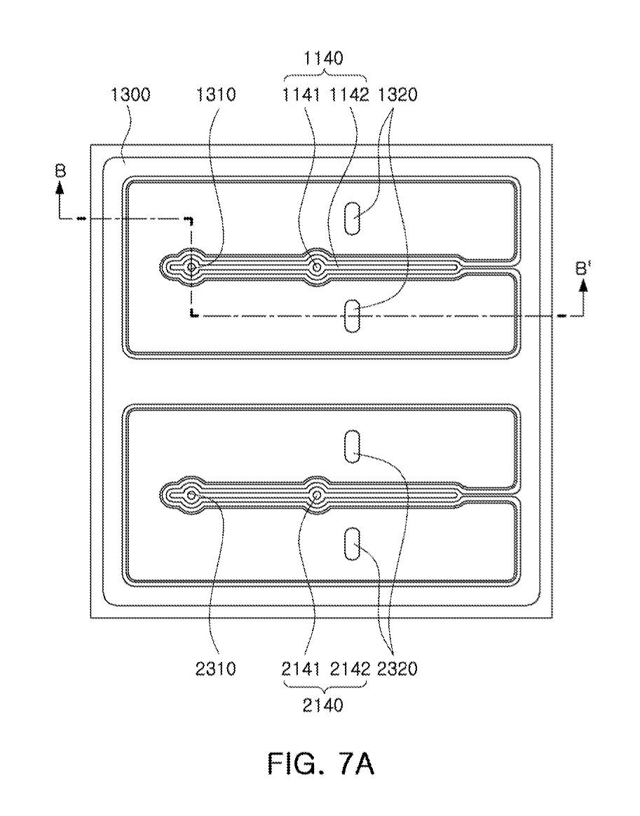

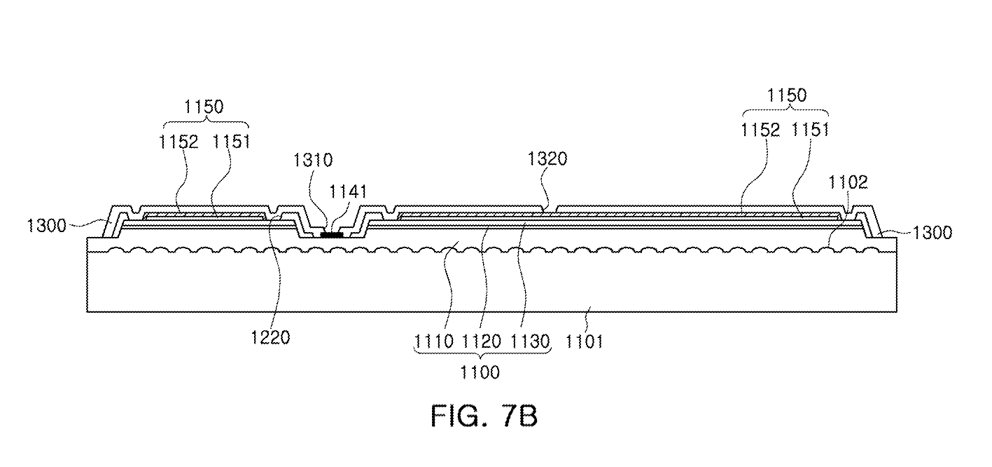

Referring to FIGS. 7A and 7B, a structure in which the second insulating layer 1300 covers surfaces of the first and second light emitting structures 1000 and 2000 may be provided. For example, the second insulating layer 1300 may be formed of an epoxy-based insulating resin. Also, the second insulating layer 1300 may include a silicon oxide or a silicon nitride and may be formed of, for example, SiO₂, SiOₓN_{y}, TiO₂, Al₂O₃, or ZrO₂.

The pad portions 1141 and 2141 of the first electrodes 1140 and 2140 and the second electrodes 1150 and 2150 may be partially exposed on the first and second conductivity-type semiconductor layers 1110 and 1130 through the plurality of openings 1310, 1320, 2310, and 2320. The plurality of openings 1310, 1320, 2310, and 2320 may be formed through dry etching such as inductive coupled plasma-reactive ion etching (ICP-RIE).

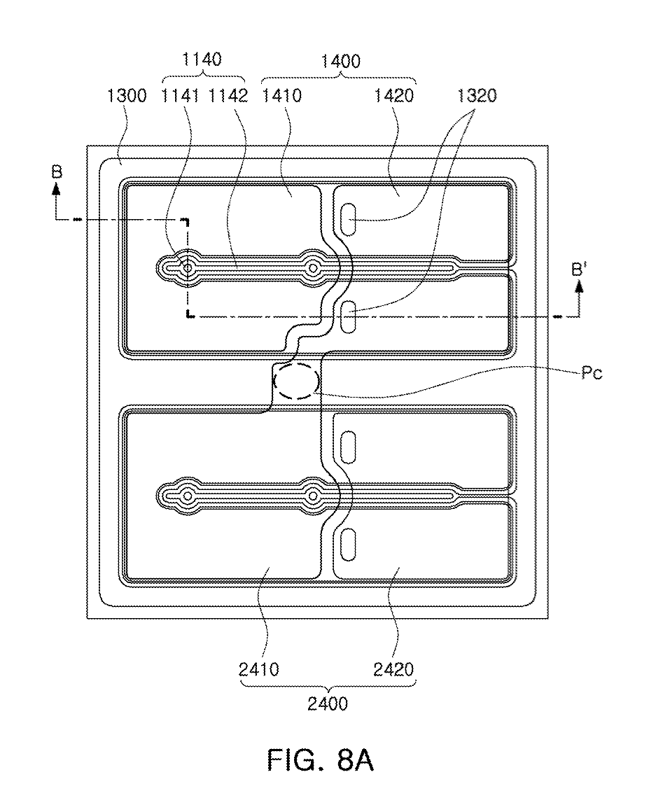

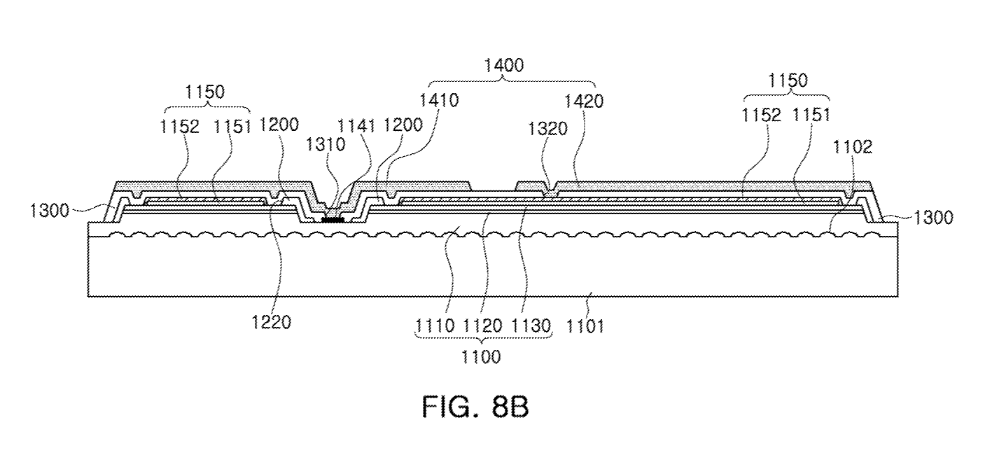

Referring to FIGS. 8A and 8B, an electrode pad 1400 may be formed on the second insulating layer 1300. The electrode pad 1400 may be connected to the first and second electrodes 1140 and 1150 exposed through the plurality of openings 1310 and 1320 so as to be electrically connected to the first conductivity-type semiconductor layer 1110 and the second conductivity-type semiconductor layer 1130, respectively.

At least two of the electrode pads 1400 may be provided on the first light emitting structure 1000 in order to electrically connect the first conductivity-type semiconductor layer 1110 and the second conductivity-type semiconductor layer 1130. Namely, a first electrode pad 1410 is electrically connected to the first conductivity-type semiconductor layer 1110 via the first electrode 1140, a second electrode pad 1420 may be electrically connected to the second conductivity-type semiconductor layer 1130 via the second electrode 1150, and the first and second electrode pads 1410 and 1420 may be separated to be electrically insulated.

First and second electrode pads 2410 and 2420 may be formed on the second insulating layer 1300 in the second light emitting structure 2000 in the same manner as the first and second electrode pads 1410 and 1420 are formed on the first light emitting structure 1000. Also, in order to electrically connect the first and second light emitting structures 1000 and 2000 in series, at least one mutual connection portion Pc connecting electrodes having the opposite polarities of the first and second light emitting structures 1000 and 2000 may be formed between the second electrode pad 1420 of the first light emitting structure 1000 and the first electrode pad 2410 of the second light emitting structure 2000. That is, as illustrated in the equivalent circuit diagram of FIG. 3, the mutual connection portion Pc may connect the electrodes having the opposite polarities of the adjacent light emitting structures 1000 and 2000 to realize a serial connection.

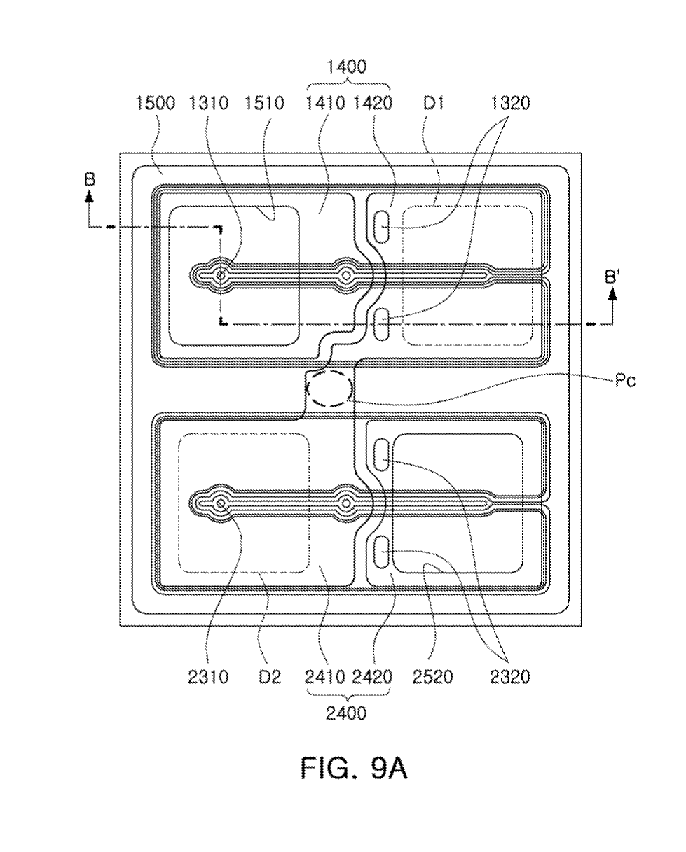

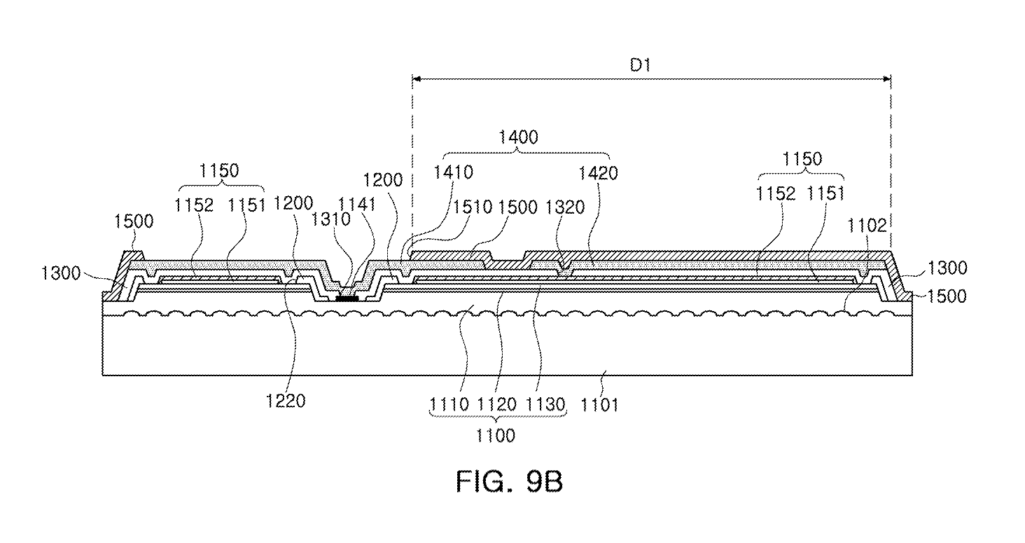

Referring to FIGS. 9A and 9B, a passivation layer 1500 may be formed to cover the electrode pads 1400 and 2400. The passivation layer 1500 may partially expose the second electrode pad 1420 of the first light emitting structure 1000 and the first electrode pad 2410 of the second light emitting structure 2000 through bonding regions 1510 and 2520.

The bonding regions 1510 and 2520 may be provided in an amount of at least two to partially expose the first electrode pad 1410 and the second electrode pad 1420, respectively. The passivation layer 1500 may be formed of the same material as that of the second insulating layer 1300.

Since a bonding region is not formed in regions D1 and D2 in which dummy solder pads 1620 and 2610 are to be disposed in a follow-up manufacturing process, the dummy solder pads 1620 and 2610 may be used for mounting the light emitting device 100 and may be electrically insulated from the light emitting structures 1000 and 2000.

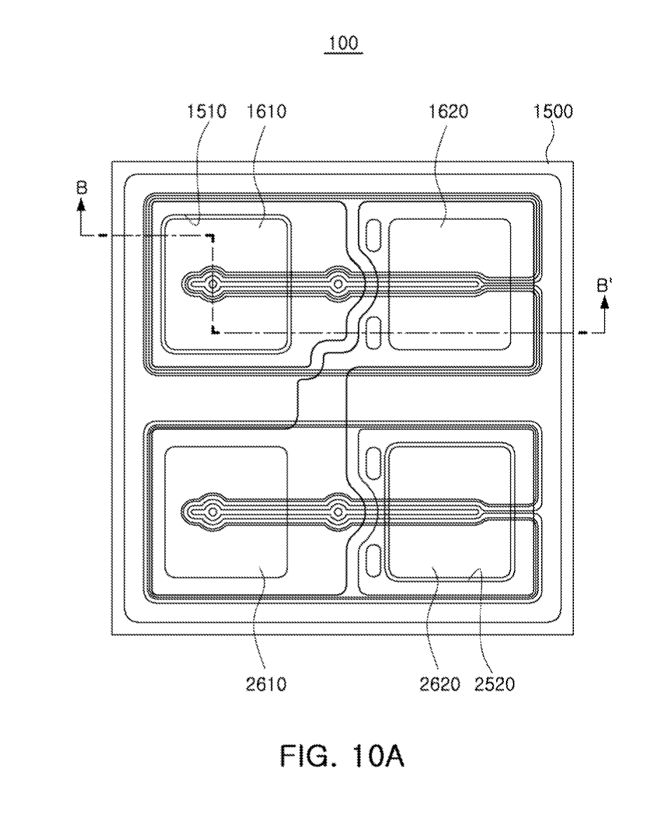

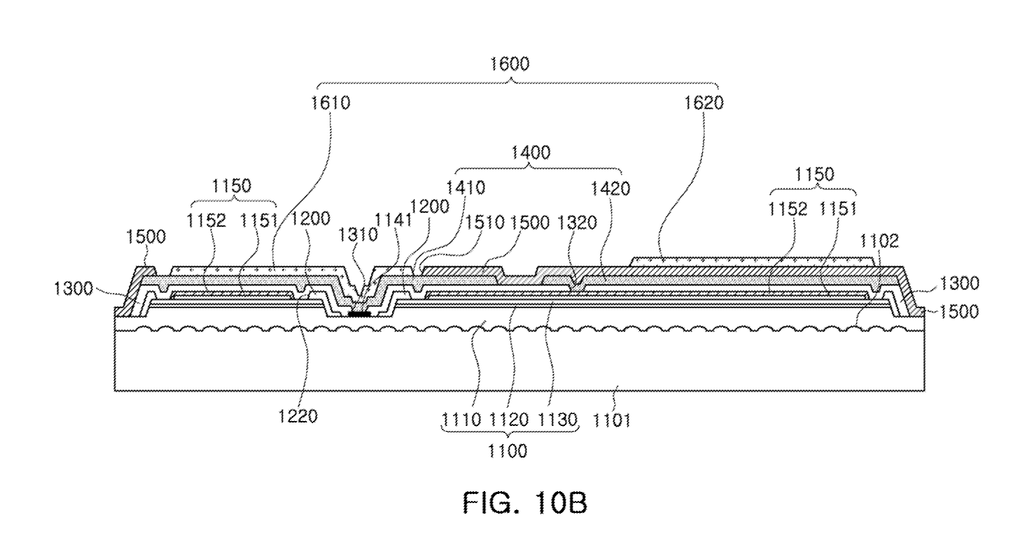

Referring to FIGS. 10A and 10B, a first solder pad 1610 and a second solder pad 2620 may be formed on the first and second electrode pads 1410 and 2420 partially exposed through the bonding regions 1510 and 2520, respectively, The first solder pad 1610 and the second solder pad 2620 may be, for example, under-bump metallurgy (UBM) layers. The number and dispositional structure of the first solder pad 1610 and the second solder pad 2620 may be variously modified, without being limited to the configuration as described above. Also, dummy solder pads 1620 and 2610 may be formed in the regions D1 and D2 described above, respectively. The first and second electrode pads 1410 and 1420 and the dummy solder pads 1620 and 2610 may be formed of the same material and may be formed to have the same shape. Also, the first and second electrode pads 1410 and 1420 and the dummy solder pads 1620 and 2610 may be formed through separate manufacturing processes or may be formed through the same process. The light emitting device 100 may be manufactured through the aforementioned process. Also, solder bumps may be disposed on the first and second solder pads 1610 and 2620 and the dummy solder pads 1620 and 2610, respectively, and the light emitting device 100 may be mounted on the package board 200 in a flip-chip manner, thereby manufacturing the light emitting device package 10.

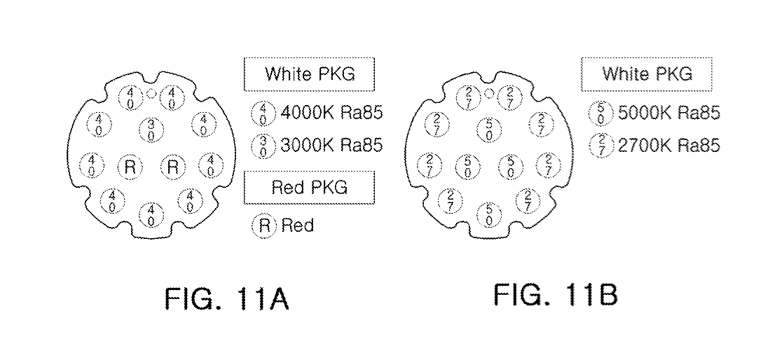

FIGS. 11A and 11B are views schematically illustrating a white light source module employing a light emitting device package according to an example embodiment.

Referring to FIGS. 11A and 11B, light source modules may include a plurality of light emitting device packages mounted on a circuit board. A plurality of light emitting device packages mounted on a single light source module may be configured as homogenous packages which generate light having the same wavelength, or as in the present example embodiment, a plurality of light emitting device packages mounted on a single light source module may be configured as heterogeneous packages which generate light having different wavelengths.

Referring to FIG. 11A, a white light source module may be configured by combining white light emitting device packages having color temperatures of 4000K and 3000K, and red light emitting device packages. The white light source module may provide white light having a color temperature that may be adjusted to range from 3000K to 4000K and having a color rendering index (CRI) Ra ranging from 105 to 100.

Referring to FIG. 11B, a white light source module includes only white light emitting device packages, and some of the packages may have white light having a different color temperature. For example, by combining a white light emitting device package having a color temperature of 2700K and a white light emitting device package having a color temperature of 5000K, white light having a color temperature that may be adjusted to range from 2700K to 5000K and having a CRI Ra of 85 to 99 may be provided. According to an example embodiment, the amount of light emitting device packages of each color temperature may vary depending on a set color temperature value. For example, in case of a lighting device in which a set value is a color temperature of about 4000K, the amount of packages corresponding to the color temperature of 4000K may be adjusted to be greater than the amount of packages corresponding to a color temperature of 3000K or the amount of red light emitting device packages.

In this manner, the heterogeneous light emitting device package is configured to include at least one of a light emitting device which emits white light by combining yellow, green, red, or orange phosphors with a blue light emitting device or a purple, blue, green, red, or infrared light emitting device, whereby a color temperature and CRI of white light may be adjusted.

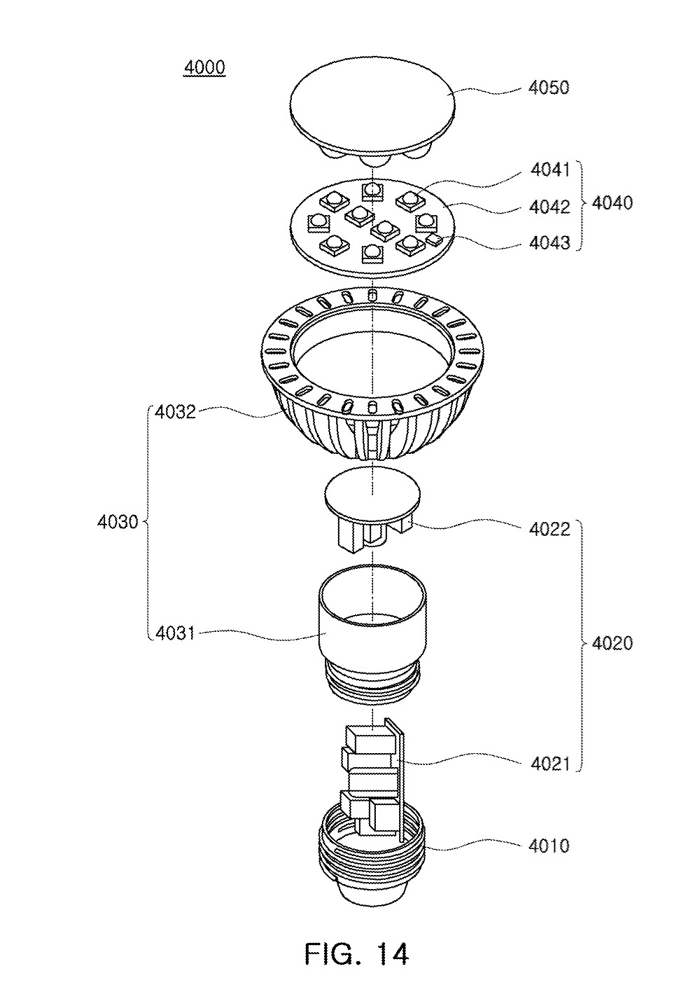

The white light source module described above may be used as a light source module 4040 of a bulb-type lighting device (“4000” of FIG. 14).

In a single light emitting device package, light having a desired color is determined according to wavelengths of an LED chip as a light emitting device, and types and mixing ratios of phosphors, and in case of white light, a color temperature and a CRI, may be adjusted.

For example, in a case in which an LED chip emits blue light, a light emitting device package including at least one of yellow, green, and red phosphors may emit white light having various color temperatures according to mixing ratios of phosphors. In contrast, a light emitting device package in which a green or red phosphor is applied to a blue LED chip may emit green or red light. In this manner, a color temperature or a CRI of white light may be adjusted by combining a light emitting device package which emits white light and a light emitting device package which emits green or red light. Also, at least one light emitting device which emits purple, blue, green, red, or infrared light may be included.

In this case, the lighting device may control a color rendering index (CRI) to range from the level of light emitted by a sodium lamp to the level of sunlight, and control a color temperature ranging from 1500K to 20000K to generate various levels of white light. If necessary, the lighting device may generate visible light having purple, blue, green, red, or orange colors, or infrared light to adjust an illumination color according to a surrounding atmosphere or mood. Also, the lighting device may generate light having a special wavelength which stimulates plant growth.

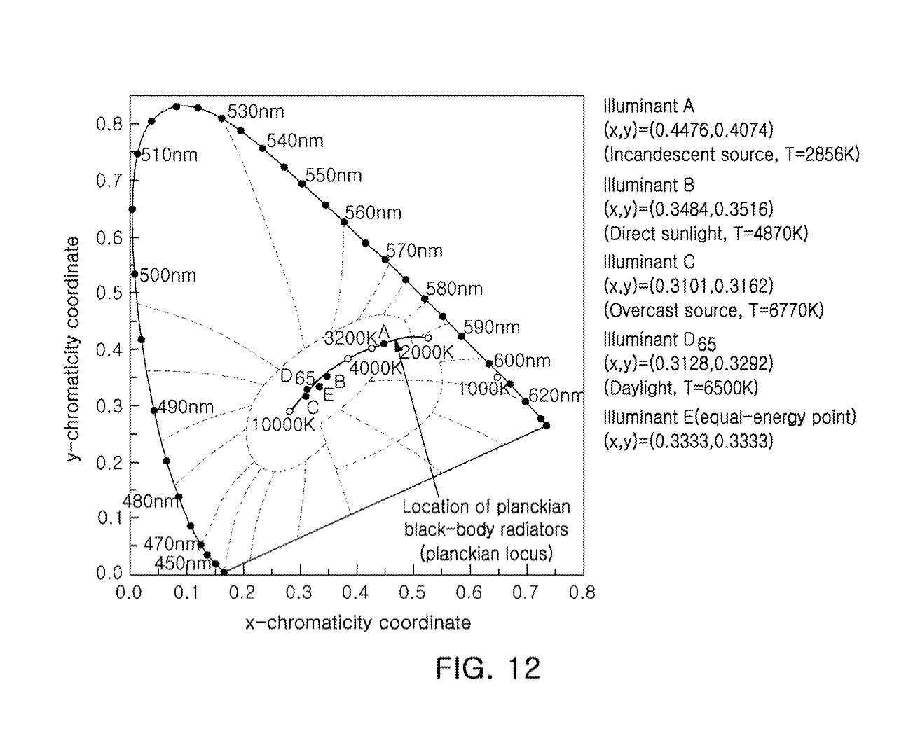

FIG. 12 is a CIE 1931 color space chromaticity diagram illustrating wavelength conversion materials that may be employed in a light emitting device package according to an example embodiment.

Referring to the CIE 1931 color space chromaticity diagram illustrated in FIG. 12, white light generated by combining yellow, green, and red phosphors with a UV or blue LED and/or by combining green and red LEDs thereto may have two or more peak wavelengths, and, as illustrated in FIG. 12, (x,y) coordinates may be positioned in a segment linking (0.4476, 0.4074), (0.3484, 0.3516), (0.3101, 0.3162), (0.3128, 0.3292), (0.3333, 0.3333) of the CIE 1931 chromaticity diagram. Alternatively, the (x,y) coordinates may be positioned in a region surrounded by the segment and a spectrum of black body radiation. A color temperature of white light corresponds to a range from about 2000K to about 20000K. In FIG. 12, white light in the vicinity of the point E (0.3333, 0.3333) present in a lower portion of the spectrum of black body radiation is in a state in which light of a yellow component is relatively weak, which may be used as a light source for illumination in a region (e.g., a building, a house, an outdoor area, etc.), for which a vivid or fresh feeling for the naked eye is desired. Thus, for example, lighting products using white light in the vicinity of the point E (0.3333, 0.3333) in the lower portion of the spectrum of black body radiation may be effectively used as lighting devices in various types of stores, e.g., stores selling groceries or clothes.

Various materials such as phosphors and/or quantum dots may be used as materials for converting a wavelength of light emitted by a semiconductor light emitting device.

Phosphors may have the following empirical formulas and colors:
Oxides: Yellow and green Y₃Al₅O₁₂:Ce, Tb₃Al₅O₁₂:Ce, Lu₃Al₅O₁₂: Ce
Silicates: Yellow and green (Ba,Sr)₂SiO₄:Eu, yellow and orange (Ba,Sr)₃SiO₅:Ce
Nitrides: Green β-SiAlON:Eu, yellow La₃Si₆N₁₁:Ce, orange α-SiAlON:Eu, red CaAlSiN₃:Eu, Sr₂Si₅N₈:Eu, SrSiAl₄N₇:Eu, SrLiAl₃N₄: Eu, Ln₄₋ₓ(Eu_{z}M_{1-z})ₓSi_{12-y}Al_{y}O_{3+x+y}N_{18-x-y}, where 0.5≦x≦3, 0<z<0.3, and 0<y≦4—Equation (1)

In Equation (1), Ln may be at least one type of element selected from the group consisting of Group IIIa elements and rare earth elements, and M may be at least one type of element selected from the group consisting of calcium (Ca), barium (Ba), strontium (Sr), and magnesium (Mg).
Fluorides: KSF-based red K₂SiF₆:Mn₄⁺, K₂TiF₆:Mn₄⁺, NaYF₄:Mn₄⁺, NaGdF₄:Mn₄⁺, K₃SiF₇:Mn⁴⁺.

Phosphor compositions should basically conform with Stoichiometry, and respective elements may be substituted with different elements of respective groups of the periodic table. For example, strontium (Sr) may be substituted with barium (Ba), calcium (Ca), magnesium (Mg), and the like, of alkali earth elements, and yttrium (Y) may be substituted with terbium (Tb), Lutetium (Lu), scandium (Sc), gadolinium (Gd), and the like. Also, europium (Eu), an activator, may be substituted with cerium (Ce), terbium (Tb), praseodymium (Pr), erbium (Er), ytterbium (Yb), and the like, according to a desired energy level, and an activator may be applied alone, or a coactivator, or the like, may be additionally applied to change characteristics.

In particular, in order to enhance reliability at high temperatures and high humidity, the fluoride-based red phosphor may be coated with a fluoride which does not contain manganese (Mn) or may further include an organic substance coated on a surface of the fluoride coating which does not contain manganese (Mn). Unlike any other phosphor, the fluoride-based red phosphor may realize a narrow full width at half maximum (FWHM) equal to or less than 40 nm, and thus, the fluoride-based red phosphor may be utilized in high resolution TVs such as UHD TVs.

Table 1 below illustrates types of phosphors in various types of fields of white light emitting devices which use a blue LED chip (wavelength: 440 nm to 460 nm) or a UV LED chip (wavelength: 380 nm to 440 nm).

TABLE 1

| Purpose | Phosphor |
|---|---|
| LED TV BLU | β-SiAlON:Eu²⁺, (Ca, Sr)AlSiN₃:Eu²⁺, |
| | La₃Si₆N₁₁:Ce³⁺, K₂SiF₆:Mn⁴⁺, SrLiAl₃N₄:Eu, Ln₄₋ₓ(Eu_{z}M_{1-z})ₓSi_{12-y}Al_{y}O_{3+x+y}N_{18-x-y} |
| | (0.5 ≦ x ≦ 3, 0 < z < 0.3, |
| | 0 < y ≦ 4), K₂TiF₆:Mn⁴⁺, NaYF₄:Mn⁴⁺, NaGdF₄:Mn⁴⁺, |
| | K₃SiF₇:Mn⁴⁺ |
| Lighting | Lu₃Al₅O₁₂:Ce³⁺, Ca-α-SiAlON:Eu²⁺, |
| | La₃Si₆N₁₁:Ce³⁺, (Ca, Sr)AlSiN₃:Eu²⁺, Y₃Al₅O₁₂:Ce³⁺, |
| | K₂SiF₆:Mn⁴⁺, SrLiAl₃N₄:Eu, Ln₄₋ₓ(Eu_{z}M_{1-z})ₓSi_{12-y}Al_{y}O_{3+x+y}N_{18-x-y} |
| | (0.5 ≦ x ≦ 3, 0 < z < 0.3, 0 < y ≦ 4), |
| | K₂TiF₆:Mn⁴⁺, NaYF₄:Mn⁴⁺, NaGdF₄:Mn⁴⁺, K₃SiF₇:Mn⁴⁺ |
| Side | Lu₃Al₅O₁₂:Ce³⁺, Ca-α-SiAlON:Eu²⁺, |
| viewing | La₃Si₆N₁₁:Ce³⁺, (Ca, Sr)AlSiN₃:Eu²⁺, Y₃Al₅O₁₂:Ce³⁺, |
| (Mobile | (Sr, Ba, Ca, Mg)₂SiO₄:Eu²⁺, K₂SiF₆:Mn⁴⁺, |
| devices, | SrLiAl₃N₄:Eu, Ln₄₋ₓ(Eu_{z}M_{1-z})ₓSi_{12-y}Al_{y}O_{3+x+y}N_{18-x-y} |
| Notebook | (0.5 ≦ x ≦ 3, 0 < z < 0.3, 0 < y ≦ 4), K₂TiF₆:Mn⁴⁺, |
| PCs) | NaYF₄:Mn⁴⁺, NaGdF₄:Mn⁴⁺, K₃SiF₇:Mn⁴⁺ |
| Electrical | Lu₃Al₅O₁₂:Ce³⁺, Ca-α-SiAlON:Eu²⁺, |
| components | La₃Si₆N₁₁:Ce³⁺, (Ca, Sr)AlSiN₃:Eu²⁺, Y₃Al₅O₁₂:Ce³⁺, |
| (Headlamps, | K₂SiF₆:Mn⁴⁺, SrLiAl₃N₄:Eu, Ln₄₋ₓ(Eu_{z}M_{1-z})ₓSi_{12-y}Al_{y}O_{3+x+y}N_{18-x-y} |
| etc.) | (0.5 ≦ x ≦ 3, 0 < z < 0.3, 0 < y ≦ 4), |
| | K₂TiF₆:Mn⁴⁺, NaYF₄:Mn⁴⁺, NaGdF₄:Mn⁴⁺, K₃SiF₇:Mn⁴⁺ |

Also, the wavelength conversion unit may be formed of wavelength conversion materials such as quantum dots (QD), and in this case, the quantum dots may be used in place of phosphors or may be mixed with phosphors so as to be used.

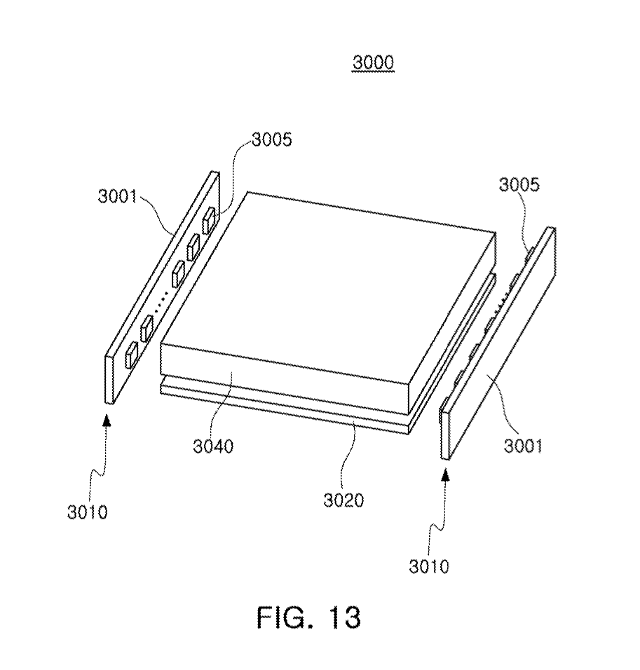

FIG. 13 is a cross-sectional view illustrating an example in which a light emitting device package according to an example embodiment is applied to a backlight unit.

Referring to FIG. 13, a backlight unit 3000 (e.g., backlight) may include a light guide plate 3040 and light source modules 3010 provided on both sides of the light guide plate 3040. Also, the backlight unit 3000 may further include a reflective plate 3020 disposed below the light guide plate 3040. The backlight unit 3000 according to the present example embodiment may be an edge type backlight unit, although example embodiments are not limited to edge type backlight units, and other types of backlight units may also be used.

According to example embodiments, the light source module 3010 may only be provided on one side of the light guide plate 3040 or may further be provided on the other side thereof. The light source module 3010 may include a printed circuit board (PCB) 3001 and a plurality of light sources 3005 mounted on an upper surface of the PCB 3001.

FIG. 14 is an exploded perspective view schematically illustrating a bulb type lamp as a lighting device employing a light emitting device package according to an example embodiment.

Referring to FIG. 14, a lighting device 4000 may include a socket 4010, a power source unit 4020 (e.g., power source), a heat dissipation unit 4030 (e.g., heat dissipator), a light source module 4040, and an optical unit 4050. According to an example embodiment, the light source module 4040 may include a light emitting device array, and the power source unit 4020 may include a light emitting device driving unit.

The socket 4010 may be configured to be replaced with an existing lighting device. Power supplied to the lighting device 4000 may be applied through the socket 4010. As illustrated in FIG. 14, the power source unit 4020 may include a first power source unit 4021 and a second power source unit 4022. The first power source unit 4021 and the second power source unit 4022 may be assembled to form the power source unit 4020. The heat dissipation unit 4030 may include an internal heat dissipation unit 4031 (e.g., internal heat dissipator) and an external heat dissipation unit 4032 (e.g., external heat dissipator). The internal heat dissipation unit 4031 may be directly connected to the light source module 4040 and/or the power source unit 4020 so as to transmit heat to the external heat dissipation unit 4032. The optical unit 4050 may be configured to evenly distribute light emitted by the light source module 4040.

The light source module 4040 may emit light to the optical unit 4050 upon receiving power from the power source unit 4020. The light source module 4040 may include one or more light emitting devices 4041, a circuit board 4042, and a controller 4043. The controller 4043 may store driving information of the light emitting devices 4041.

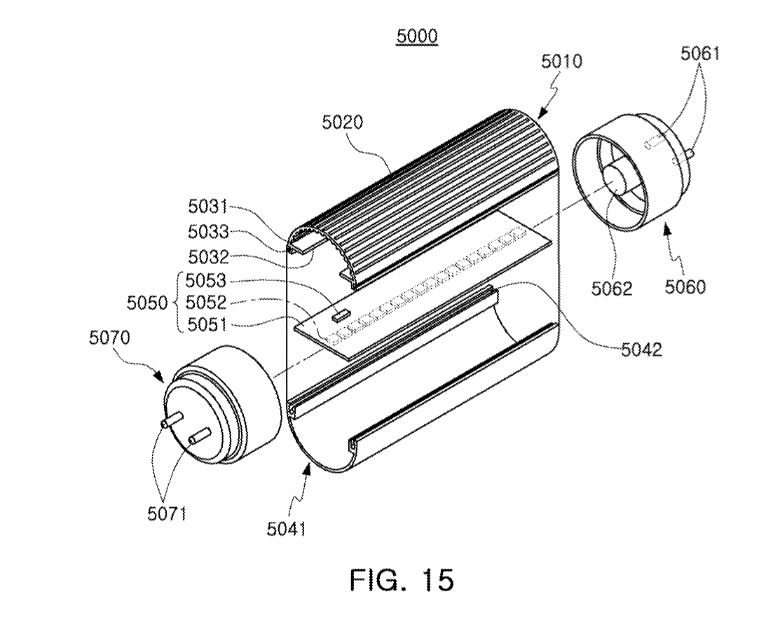

FIG. 15 is an exploded perspective view schematically illustrating a bar type lamp as a lighting device employing a light emitting device package according to an example embodiment.

In detail, a lighting device 5000 includes a heat dissipation member 5010, a cover 5041, a light source module 5050, a first socket 5060, and a second socket 5070. A plurality of heat dissipation fins 5020 and 5031 may be formed in a concavo-convex pattern on an internal or/and external surface of the heat dissipation member 5010, and the heat dissipation fins 5020 and 5031 may be designed to have various shapes and intervals (spaces) therebetween. A support 5032 having a protrusion shape is formed on an inner side of the heat dissipation member 5010. The light source module 5050 may be fixed to the support 5032. Stoppage protrusions 5033 may be formed on both ends of the heat dissipation member 5010.

The stoppage recesses 5042 may be formed in the cover 5041, and the stoppage protrusions 5033 of the heat dissipation member 5010 may be coupled to the stoppage recesses 5042 in a hook coupling manner. The positions of the stoppage recesses 5042 and the stoppage protrusions 5033 may be interchanged.

The light source module 5050 may include a light emitting device array. The light source module 5050 may include a PCB 5051, a light source 5052, and a controller 5053. As described above, the controller 5053 may store driving information of the light source 5052. Circuit wirings are formed on the PCB 5051 to operate the light source 5052. Also, components for operating the light source 5052 may be provided on the PCB 5051.

The first and second sockets 5060 and 5070, a pair of sockets, are coupled to both ends of the cylindrical cover unit including the heat dissipation member 5010 and the cover 5041. For example, the first socket 5060 may include electrode terminals 5061 and a power source device 5062, and dummy terminals 5071 may be disposed on the second socket 5070. Also, an optical sensor and/or a communications module may be installed in either the first socket 5060 or the second socket 5070. For example, the optical sensor and/or the communications module may be installed in the second socket 5070 in which the dummy terminals 5071 are disposed. In another example, the optical sensor and/or the communications module may be installed in the first socket 5060 in which the electrode terminals 5061 are disposed.

According to example embodiments, an Internet of things (IoT) device may include devices having an accessible wired or wireless interface, and may communicate with at least one or more other devices through the wired or wireless interface to transmit or receive data. The accessible interface may include a modem communications interface enabling access to a wired local area network (LAN), a wireless location area network (WLAN) such as wireless fidelity (Wi-Fi), a wireless personal area network (WPAN) such as Bluetooth, or a mobile cellular network such as a wireless universal serial bus (USB), ZigBee, near field communication (NFC), radio-frequency identification (RFID), power line communication (PLC), or 3^{rd} generation (3G), 4^{th} generation (4G), or long term evolution (LTE). The Bluetooth interface may support Bluetooth low energy (BLE).

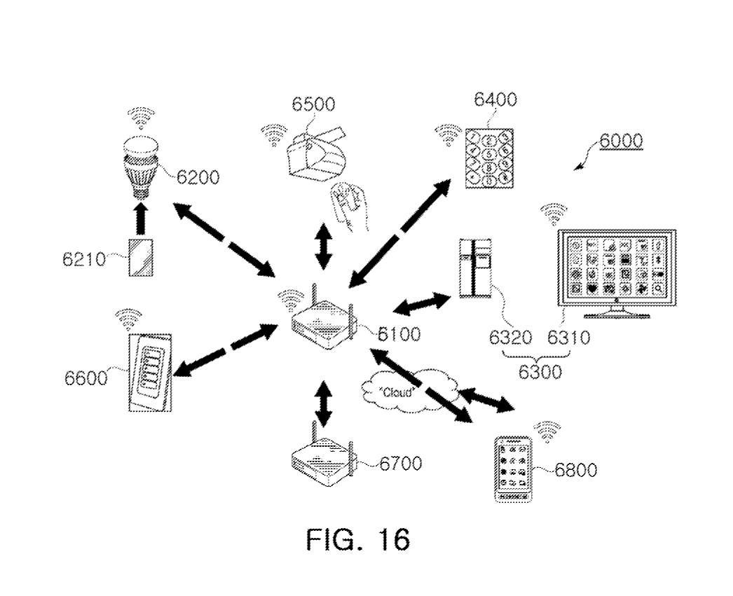

FIG. 16 is a view schematically illustrating an indoor lighting control network system in which a light emitting device package according to an example embodiment may be employed.

A network system 6000 may be a complex smart lighting-network system combining lighting technology using a light emitting device such as an LED, or the like, Internet of things (IoT) technology, wireless communications technology, and the like. The network system 6000 may be realized using various lighting devices and wired or wireless communications devices, and may be realized by a sensor, a controller, a communications unit, software for network control and maintenance, and the like.

The network system 6000 may also be applied to an outdoor space such as a park or an area around a street, as well as to a closed space defined by walls, such as a house or an office. The network system 6000 may be implemented on the basis of the IoT environment in order to collect and process a variety of types of information and provide the same to users. An LED lamp 6200 included in the network system 6000 may serve to check and control operational states of other devices 6300 to 6800 included in the IoT environment on the basis of a function such as visible light communications, or the like, of the LED lamp 6200, as well as to receive information regarding a surrounding environment from a gateway 6100 and to control lighting of the LED lamp 6200.

Referring to FIG. 16, the network system 6000 may include the gateway 6100 which processes data transmitted and received according to different communications protocols, the LED lamp 6200 configured to communicate with the gateway 6100 and which includes an LED light emitting device, and a plurality of devices 6300 to 6800 configured to communicate with the gateway 6100 according to various wireless or wired communications schemes. In order to realize the network system 6000 on the basis of the IoT environment, each of the devices 6300 to 6800, as well as the LED lamp 6200, may include at least one communications module. In an example embodiment, the LED lamp 6200 may be configured to communicate with the gateway 6100 according to wireless communications protocols such as Wi-Fi, ZigBee, or Li-Fi, and to this end, the LED lamp 6200 may include at least one communications module 6210 for a lamp.

As mentioned above, the network system 6000 may be applied to an outdoor space such as a park or a street, as well as to an indoor space such as a house or an office. When the network system 6000 is applied to a house, the plurality of devices 6300 to 6800 included in the network system and configured to communicate with the gateway 6100 on the basis of the IoT technology may include a home appliance 6300 such as a television 6310 or a refrigerator 6320, a digital door lock 6400, a garage door lock 6500, a light switch 6600 installed on a wall, or the like, a router 6700 for relaying a wireless communications network, and a mobile device 6800 such as a smartphone, a tablet, or a laptop computer.

In the network system 6000, the LED lamp 6200 may check operational states of various devices 6300 to 6800 using the wireless communications network (ZigBee, Wi-Fi, Li-Fi, etc.) installed in a household or may automatically control illumination of the LED lamp 6200 according to a surrounding environment or situation. Also, the devices 6300 to 6800 included in the network system 600 may be controlled using Li-Fi communications which employ visible light emitted by the LED lamp 6200.

First, the LED lamp 6200 may automatically adjust illumination of the LED lamp 6200 on the basis of information of a surrounding environment transmitted from the gateway 6100 through the communications module 6210 for a lamp or information of a surrounding environment collected from a sensor installed in the LED lamp 6200. For example, brightness of illumination of the LED lamp 6200 may be automatically adjusted according to types of programs broadcast on the television 6310 or brightness of a screen. To this end, the LED lamp 6200 may receive operation information of the TV 6310 from the communications module 6210 for a lamp connected to the gateway 6100. The communications module 6210 for a lamp may be integrally modularized with a sensor and/or a controller included in the LED lamp 6200.

For example, in a case in which a program broadcast on a TV is a drama, a color temperature of illumination may be decreased to be 12000K or lower, (to 6000K, for example), and a color tone may be adjusted according to preset values, to provide a cozy atmosphere. Conversely, when a program is a comedy, the network system 6000 may be configured so that a color temperature of illumination is increased to 6000K or higher according to a preset value and illumination is adjusted to white illumination based on a blue color.

Also, in a case in which no one is at home, when a predetermined time has lapsed after a digital door lock 6400 is locked, all of the turned-on LED lamps 6200 are turned off to prevent wastage of electricity. Also, in a case in which a security mode is set through the mobile device 6800, or the like, when the digital door lock 6400 is locked with nobody at home, the LED lamp 6200 may be maintained in a turned-on state.

An operation of the LED lamp 6200 may be controlled according to information regarding surrounding environments collected through various sensors connected to the network system 6000. For example, in a case in which the network system 6000 is implemented in a building, lighting equipment, a position sensor, and a communications module are combined in the building, and position information of people in the building is collected and lighting is turned on or turned off, or the collected information may be provided in real time to effectively manage facilities or effectively utilize idle space. In general, a lighting device such as the LED lamp 6200 may be disposed in almost every space of each floor of a building, and thus, various types of information of the building may be collected through a sensor integrally provided with the LED lamp 6200 and used for managing facilities and utilizing idle space.

The LED lamp 6200 may be combined with an image sensor, a storage device, and the communications module 6210 for a lamp, to be utilized as a device for maintaining building security or to sense and cope with an emergency situation. For example, in a case in which a smoke or temperature sensor, or the like, is attached to the LED lamp 6200, a fire may be promptly sensed and damage may be minimized. Also, brightness of lighting may be adjusted in consideration of weather or an amount of sunshine, thereby saving energy and providing an agreeable illumination environment.

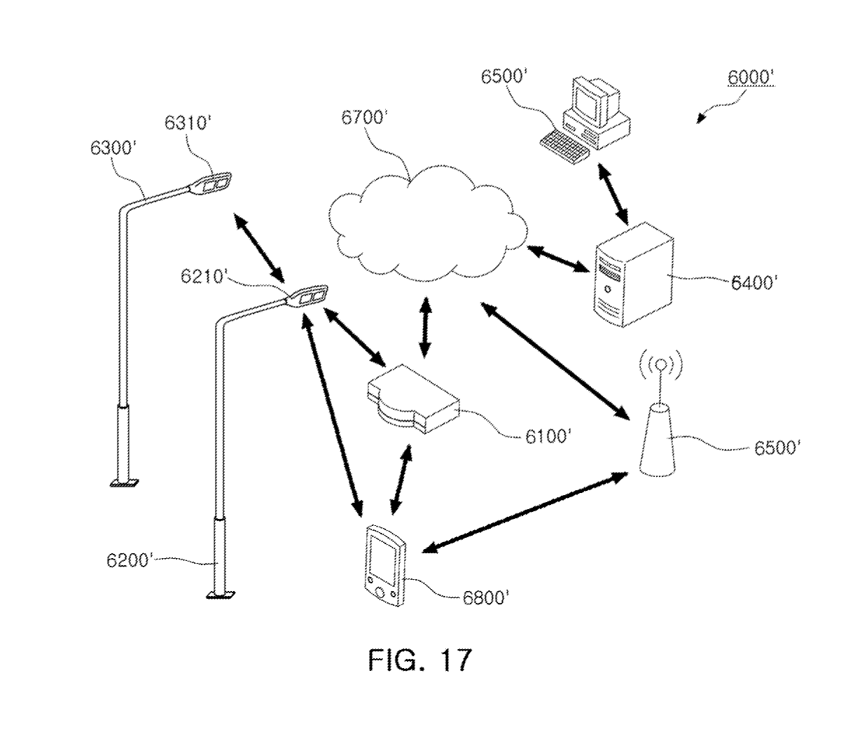

FIG. 17 is a view illustrating an open network system in which a light emitting device package according to an example embodiment may be employed.

Referring to FIG. 17, a network system 6000′ according to the present example embodiment may include a communications connection device 6100′, a plurality of lighting fixtures 6200′ and 6300′ installed at predetermined intervals and configured to communicate with the communications connection device 6100′, a server 6400′, a computer 6500′ managing the server 6400′, a communications base station 6600′, a communications network 6700′, a mobile device 6800′, and the like.

Each of the plurality of lighting fixtures 6200′ and 6300′ installed in an open outer space such as a street or a park may include smart engines 6210′ and 6310′, respectively. The smart engines 6210′ and 6310′ may include a light emitting device which emits light, a driver which drives the light emitting device, a sensor which collects information of a surrounding environment, a communications module, and the like. The smart engines 6210′ and 6310′ may communicate with other neighboring equipment by using a communications module compatible with communications protocols such as Wi-Fi, ZigBee, and Li-Fi.

For example, one smart engine 6210′ may be connected to communicate with another smart engine 6310′. In this case, a Wi-Fi extending technique (Wi-Fi mesh) may be applied to communications between the smart engines 6210′ and 6310′. The at least one smart engine 6210′ may be connected to the communications connection device 6100′ connected to the communications network 6700′ by wired or wireless communications. In order to increase communications efficiency, some smart engines 6210′ and 6310′ may be grouped and connected to the single communications connection device 6100′.

The communications connection device 6100′ may be an access point (AP) available for wired/wireless communications, which may relay communications between the communications network 6700′ and other equipment. The communications connection device 6100′ may be connected to the communications network 6700′ in either a wired manner or a wireless manner, and for example, the communications connection device 6100′ may be mechanically received in any one of the lighting fixtures 6200′ and 6300′.

The communications connection device 6100′ may be connected to the mobile device 6800′ through a communications protocol such as Wi-Fi, or the like. A user of the mobile device 6800′ may receive surrounding environment information collected by the plurality of smart engines 6210′ and 6310′ through the communications connection device 6100′ connected to the smart engine 6210′ of the lighting fixture 6200′ adjacent to the mobile device 6800′. The surrounding environment information may include nearby traffic information, weather information, and the like. The mobile device 6800′ may be connected to the communications network 6700′ according to a wireless cellular communications scheme such as 3G or 4G through the communications base station 6600′.

The server 6400′ connected to the communications network 6700′ may receive information collected by the smart engines 6210′ and 6310′ respectively installed in the lighting fixtures 6200′ and 6300′ and may monitor an operational state, or the like, of each of the lighting fixtures 6200′ and 6300′. In order to manage the lighting fixtures 6200′ and 6300′ on the basis of the monitoring results of the operational states of the lighting fixtures 6200′ and 6300′, the server 6400′ may be connected to the computer 6500′ providing a management system. The computer 6500′ may execute software, or the like, capable of monitoring and managing operational states of the lighting fixtures 6200′ and 6300′, and specifically, operational states of the smart engines 6210′ and 6310′.

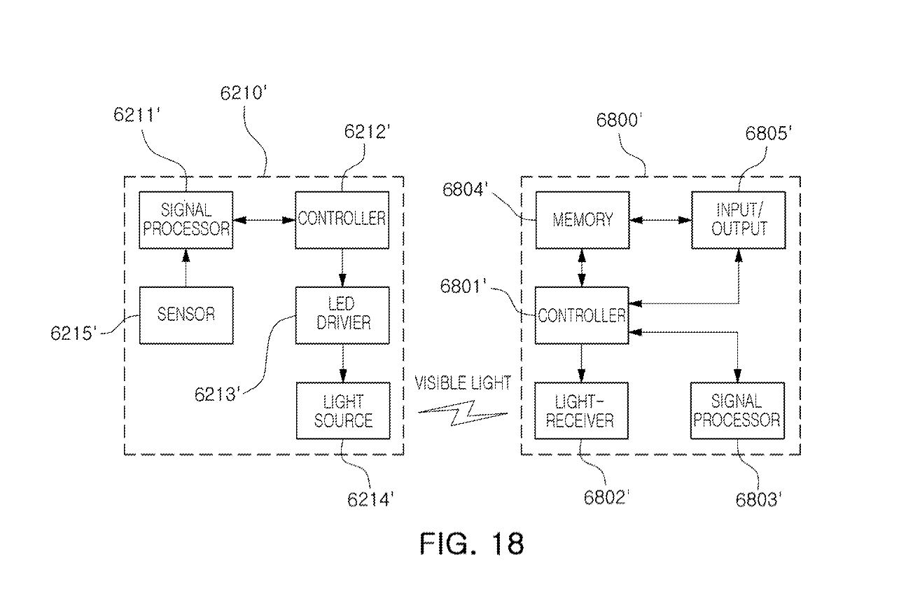

FIG. 18 is a block diagram illustrating a communications operation between a smart engine of a lighting fixture and a mobile device according to visible light communications (VLC) (or light fidelity (Li-Fi)) in which a light emitting device package according to an example embodiment may be employed.

Referring to FIG. 18, the smart engine 6210′ may include a signal processing unit 6211′ (e.g., signal processor), a control unit 6212′ (e.g., controller), an LED driver 6213′, a light source unit 6214′ (e.g., light source), a sensor 6215′, and the like. The mobile device 6800′ which is connected to and communicates with the smart engine 6210′ by visible light communications may include a control unit 6801′ (e.g., controller), a light receiving unit 6802′ (e.g., light receiver), a signal processing unit 6803′ (e.g., signal processor), a memory 6804′, an input/output unit 6805′, and the like.

The visible light communications (VLC) technology (or light fidelity (Li-Fi)) is a wireless communications technology for transferring information wirelessly by using light within the visible wavelength band visible to the naked eye. The visible light communications technology is distinguished from existing wired optical communications technology and infrared data association (IrDA) in that visible light communications technology uses light having a visible light wavelength band, namely, a particular visible light frequency from, for example, the light emitting device package according to the example embodiments described above and is distinguished from the existing wired optical communications technology in that a communications environment is based on a wireless scheme. Also, unlike RF wireless communications, the VLC technology (or Li-Fi) has excellent convenience and physical security properties as the VLC technology can be freely used without being regulated or needing permission with respect to frequency usage, and is differentiated in that a user can physically check a communications link, and above all, the VLC technology (or Li-Fi) has convergence technology features that obtain both a unique purpose as a light source and a communications function.

The signal processing unit 6211′ of the smart engine 6210′ may process data intended to be transmitted and received by VLC. In an example embodiment, the signal processing unit 6211′ may process information collected by the sensor 6215′ into data and transmit the processed data to the control unit 6212′. The control unit 6212′ may control operations of the signal processing unit 6211′, the LED driver 6213′, and the like, and in particular, the control unit 6212′ may control an operation of the LED driver 6213′ on the basis of data transmitted from the signal processing unit 6211′. The LED driver 6213′ emits the light source unit 6214′ according to a control signal transmitted from the control unit 6212′, thereby transmitting data to the mobile device 6800′.

The mobile device 6800′ may include the light receiving unit 6802′ for recognizing visible light including data, in addition to the control unit 6801′, the memory 6804′ which stores data, the input/output unit 6805′ which includes various components such as a display, a touch screen, an audio output unit, and the like, and the signal processing unit 6803′. The light receiving unit 6802′ may sense visible light and convert the sensed visible light into an electrical signal, and the signal processing unit 6803′ may decode data included in the electrical signal converted by the light receiving unit 6802′. The control unit 6801′ may store the data decoded by the signal processing unit 6803′ in the memory 6804′ or may output the decoded data through the input/output unit 6805′ to allow the user to recognize the data.

As set forth above, according to example embodiments, a light emitting device package may include a package board having a simple design.

While example embodiments have been shown and described above, it will be apparent to those skilled in the art that modifications and variations could be made without departing from the scope of the example embodiments as defined by the appended claims.

What is claimed is:

1. A light emitting device package comprising:
a package board comprising a first electrode structure and a second electrode structure; and
a light emitting device mounted on the package board and configured to emit light,
wherein the light emitting device comprises:
light emitting structures provided on a growth substrate, electrically connected in series, and comprising an input terminal and an output terminal;
a first solder pad and a second solder pad electrically connected to the input terminal and the output terminal, respectively, and in contact with the first and second electrode structures; and
dummy solder pads provided on the light emitting structures and electrically insulated from the light emitting structures.

2. The light emitting device package of claim 1, wherein each light emitting structure of the light emitting structures comprises a first conductivity-type semiconductor layer, a second conductivity-type semiconductor layer, and an active layer provided between the first conductivity-type semiconductor layer and the second conductivity-type semiconductor layer,
wherein in each light emitting structure of the light emitting structures, portions of the active layer and the second conductivity-type semiconductor layer are removed to expose a portion of an upper surface of the first conductivity-type semiconductor layer, and
wherein each light emitting structure of the light emitting structures further comprises first and second electrodes respectively connected to the first and second conductivity-type semiconductor layers.

3. The light emitting device package of claim 2, wherein each light emitting structure of the light emitting structures further comprises a first electrode pad and a second electrode pad connected to the first and second electrodes,
wherein the light emitting structures are connected in series by a mutual connection portion connecting the first or second electrode pad of one of the light emitting structures to the first or second electrode pad of another one of the light emitting structures adjacent to the one light emitting structure.

4. The light emitting device package of claim 3, further comprising a passivation layer covering the light emitting structures and having an opening exposing a region of the first or second electrode pad respectively provided at the input terminal and the output terminal of the light emitting structures.

5. The light emitting device package of claim 4, wherein the passivation layer is interposed between the light emitting structures and the dummy solder pads.

6. The light emitting device package of claim 1, wherein the dummy solder pads have the same shape as the first and second solder pads.

7. The light emitting device package of claim 5, wherein the first and second electrode structures of the package board are in contact with the dummy solder pads.

8. The light emitting device package of claim 7, wherein at least one of the first and second electrode pads and at least one of the dummy solder electrodes are connected to the first and second electrode structures.

9. The light emitting device package of claim 1, wherein the first and second solder pads and the dummy solder pads have a same height, and
wherein the height is a distance in a direction perpendicular to a surface at which the dummy solder pads contact the light emitting structures.

10. The light emitting device package of claim 1, wherein the dummy solder pads are formed of a material having a composition that is the same as a composition of the first and second solder pads.

11. The light emitting device package of claim 4, wherein the passivation layer comprises a first insulating layer having a first refractive index and a second insulating layer having a second refractive index which is stacked on the first insulating layer in an alternating fashion, to thereby form a distributed Bragg reflector (DBR).

12. The light emitting device package of claim 11, wherein the first insulating layer and the second insulating layer are formed of a material selected from the group consisting of SiOₓ, SiNₓ, Al₂O₃, HfO, TiO₂, ZrO, and combinations thereof.

13. A light emitting device package comprising:
a package board having a first electrode structure and a second electrode structure; and
a light emitting device mounted on the package board and configured to emit light,
wherein the light emitting device comprises:
light emitting structures provided on a growth substrate and comprising an input terminal and an output terminal, each of the light emitting structures comprising a first electrode and a second electrode;
a mutual connection portion connecting one of the first or second electrodes of one of the light emitting structures to one of the first or second electrodes of another of the light emitting structures adjacent to the one light emitting structure to electrically connect the light emitting structures in series;
a first solder pad and a second solder pad electrically connected to the input terminal and the output terminal, respectively, and in contact with the first and second electrode structures; and
dummy solder pads provided on the light emitting structures, electrically insulated from the light emitting structures, and in contact with the first and second electrode structures.

14. The light emitting device package of claim 13, wherein one of the first and second solder pads and one of the dummy solder pads are connected to the first and second electrode structures, respectively.

15. The light emitting device package of claim 13, wherein one of the dummy solder pads is provided on each of the light emitting structures.

16. A light emitting device package comprising:
a package board comprising electrodes; and
a light emitting device comprising:
light emitting structures configured to emit light; and
solder pads connecting the light emitting structures to the electrodes,
wherein first solder pads among the solder pads are functional solder pads configured to supply power from the electrodes to first portions of the light emitting structures, and second solder pads among the solder pads are non-functional solder pads configured to connect second portions of the light emitting structures, spaced apart from the first portions, to the electrodes.

17. The light emitting device package of claim 16, wherein the first solder pads and second solder pads form a symmetrical pattern.

18. The light emitting device package of claim 16, wherein the second solder pads are nonresponsive to electrical signals.

19. The light device package of claim 16, wherein the first solder pads and the second solder pads comprise under-bump metallurgy (UBM) layers.

20. The light device package of claim 16, wherein the first solder pads and the second solder pads are evenly distributed across a surface at which the light emitting device connects to the package board.
